(19) United States
(12) Patent Application Publication
(10) Pub. No.: US 2025/0351594 A1
(43) Pub. Date: Nov. 13, 2025

(54) IMAGE SENSOR

(71) Applicant: Samsung Electronics Co., Ltd., Suwon-si (KR)

(72) Inventors: Daehoon KIM, Suwon-si (KR); Junha KANG, Suwon-si (KR); Jongeun PARK, Suwon-si (KR)

(73) Assignee: Samsung Electronics Co., Ltd., Suwon-si (KR)

(21) Appl. No.: 19/006,520

(22) Filed: Dec. 31, 2024

(30) Foreign Application Priority Data
May 10, 2024 (KR) 10-2024-0062180

(51) Int. Cl. H10F 39/00

(52) U.S. Cl. CPC H10F 39/8023; H10F 39/811; H10F 39/8037

(57) ABSTRACT

Provided is an image sensor. The image sensor includes a first substrate, a first floating diffusion region disposed in the first substrate, a source follower gate electrode disposed on the first substrate, and a first source region disposed on one side of the source follower gate electrode in the first substrate and spaced apart from the first floating diffusion region, wherein in a plan view, the first source region includes a main portion adjacent to a sidewall of the source follower gate electrode and a protrusion protruding from the main portion and adjacent to the first floating diffusion region.

### CROSS-REFERENCE TO RELATED APPLICATIONS

This U.S. non-provisional patent application claims priority under 35 U.S.C. § 119 of Korean Patent Application No. 10-2024-0062180, filed on May 10, 2024, the entire contents of which are hereby incorporated by reference.

### BACKGROUND

The present disclosure herein relates to an image sensor.

An image sensor is a semiconductor device that is configured to convert an optical image into an electrical signal. The image sensor may be classified into a charge coupled device (CCD) type, a complementary metal-oxide-semiconductor (CMOS) type, and/or the like. The CMOS type image sensor may also be abbreviated to as CIS. The CIS may include a plurality of two-dimensionally arranged pixels. Each of the pixels includes a photodiode. The photodiode serves to convert incident light into an electrical signal.

### SUMMARY

The present disclosure provides an image sensor capable of realizing a clear image.

An embodiment of the inventive concepts provides an image sensor including a first substrate; a first floating diffusion region in the first substrate; a source follower gate electrode on the first substrate; and a first source region on one side of the source follower gate electrode in the first substrate and spaced apart from the first floating diffusion region, wherein in a plan view, the first source region includes a main portion adjacent to a sidewall of the source follower gate electrode and a protrusion protruding from the main portion and adjacent to the first floating diffusion region.

In an embodiment of the inventive concepts, an image sensor includes a first substrate; a first floating diffusion region in the first substrate; a source follower gate electrode on the first substrate; a ground region in the first substrate; and a first source region on one side of the source follower gate electrode in the first substrate, spaced apart from the first floating diffusion region, and interposed between the first floating diffusion region and the ground region.

In an embodiment of the inventive concepts, an image sensor includes a first substrate; a source follower gate electrode on the first substrate; a first source region on one side of the source follower gate electrode and in the first substrate; a first floating diffusion region in the first substrate and spaced apart from the first source region; a first interlayer insulating layer covering an upper surface of the first substrate; a second substrate on the first interlayer insulating layer such that the first interlayer insulating layer is between the first substrate and the second substrate; a second floating diffusion region in the second substrate; a transfer gate electrode on a lower surface of the second substrate and adjacent to the second floating diffusion region; second source regions in the second substrate and at least partially surrounding the second floating diffusion region; a color filter on the second substrate; and a microlens on the color filter, wherein the second source regions are electrically connected to the first source region, and the second floating diffusion region is electrically connected to the first floating diffusion region.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a schematic plan view of a second semiconductor chip of an image sensor according to embodiments of the inventive concepts;

FIG. 2 is a schematic plan view of a third semiconductor chip of an image sensor according to embodiments of the inventive concepts;

FIG. 3 is a cross-sectional view taken along line A-A′ of FIG. 1 or 2 according to embodiments of the inventive concepts;

FIG. 4A is a circuit diagram of an image sensor according to embodiments of the inventive concepts;

FIG. 4B is an enlarged view of portion P1 in the circuit diagram of FIG. 4A;

FIGS. 5A to 5E are plan views of a second semiconductor chip of an image sensor according to embodiments of the inventive concepts;

FIGS. 6A and 6B are plan views of a second semiconductor chip of an image sensor according to embodiments of the inventive concepts;

FIGS. 7A to 7C are plan views of a second semiconductor chip of an image sensor according to embodiments of the inventive concepts;

FIG. 8 is a plan view of a second semiconductor chip of an image sensor according to embodiments of the inventive concepts;

FIG. 9 is a plan view of a third semiconductor chip of an image sensor according to embodiments of the inventive concepts;

FIG. 10 is a cross-sectional view taken along line A-A′ of FIG. 9 according to embodiments of the inventive concepts;

FIGS. 11A and 11B are plan views of a third semiconductor chip of an image sensor according to embodiments of the inventive concepts;

FIGS. 12A and 12B are cross-sectional views taken along line B-B′ of FIG. 11B according to embodiments of the inventive concepts;

FIGS. 13 to 15 are plan views of a third semiconductor chip of an image sensor according to embodiments of the inventive concepts;

FIG. 16 is a partial cross-sectional view taken along line C-C′ of FIG. 15 according to embodiments of the inventive concepts;

FIG. 17 is a plan view of a third semiconductor chip of an image sensor according to embodiments of the inventive concepts;

FIG. 18 is a plan view of a second semiconductor chip of an image sensor according to embodiments of the inventive concepts;

FIG. 19 is a cross-sectional view taken along line D-D′ of FIG. 18 according to embodiments of the inventive concepts;

FIGS. 20 and 21 are plan views of a second semiconductor chip of an image sensor according to embodiments of the inventive concepts; and

FIGS. 22 and 23 are plan views of a second semiconductor chip of an image sensor according to embodiments of the inventive concepts.

### DETAILED DESCRIPTION

Hereinafter, embodiments according to the inventive concepts will be described in more detail with reference to the accompanying drawings in order to more specifically describe the inventive concepts. Herein, numerical terms indicating order, such as first, second, etc., are used to distinguish elements having the same/similar functions, and the ordinal numbers may be interchanged according to the order in which the terms are mentioned. Additionally, the numerical terms do not indicate a number of elements, else expressly indicated otherwise. For example, “twenty-second” and “twenty-third” may be used to distinguish a twenty-second element of one embodiment from a twenty-third element of another embodiment without requiring an additional twenty-one elements in either embodiment.

Like reference numerals in the drawings denote like components, and sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. It will also be understood that spatially relative terms, such as “above,” “top,” “vertical,” “lateral,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

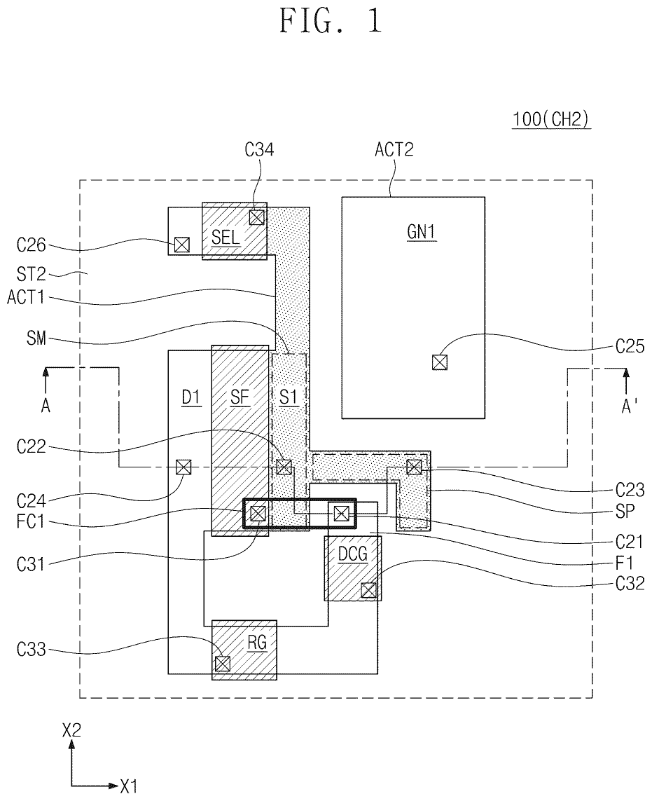

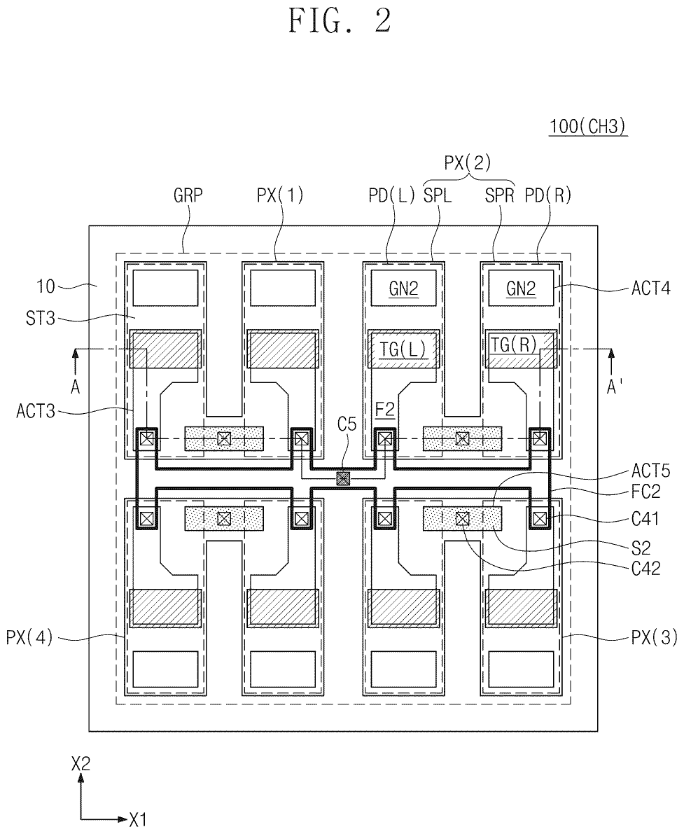

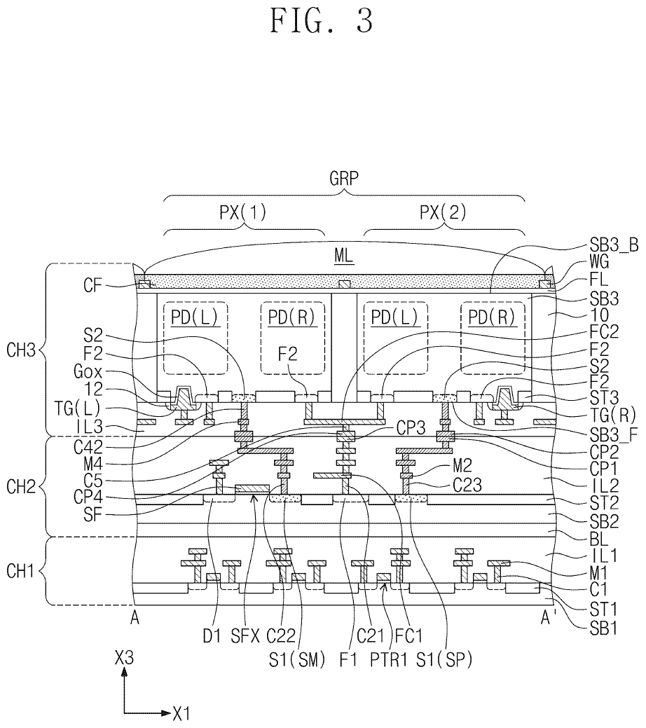

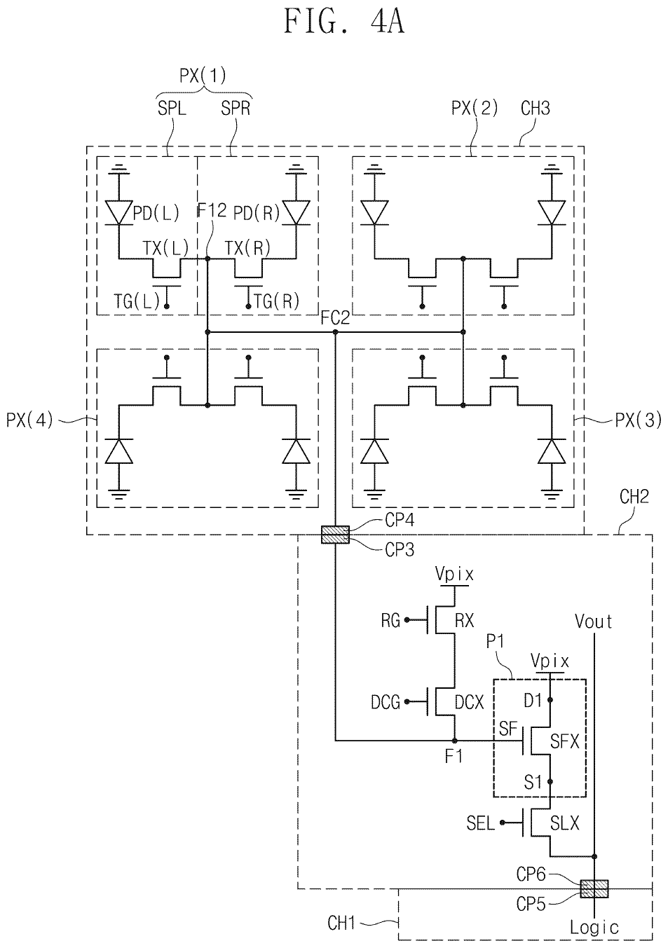

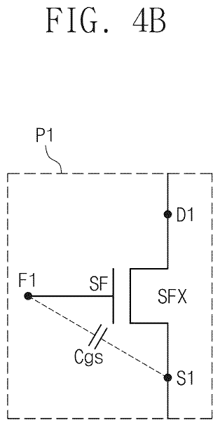

FIG. 1 is a schematic plan view of a second semiconductor chip of an image sensor according to embodiments of the inventive concepts. FIG. 2 is a schematic plan view of a third semiconductor chip of an image sensor according to embodiments of the inventive concepts. FIG. 3 is a cross-sectional view taken along line A-A′ of FIGS. 1 and/or 2 according to embodiments of the inventive concepts. FIG. 4A is a circuit diagram of an image sensor according to embodiments of the inventive concepts. FIG. 4B is an enlarged view of portion P1 in the circuit diagram of FIG. 4A.

Referring to FIGS. 1 to 4A, an image sensor 100 according to the inventive concepts includes first to third semiconductor chips CH1, CH2, and CH3 which are sequentially stacked. Each of the semiconductor chips CH1, CH2, and CH3 may be also referred to as a “sub chip”. The first semiconductor chip CH1 may be a logic circuit chip. The first semiconductor chip CH1 includes a first substrate SB1, first shallow isolation parts ST1, first peripheral transistors PTR1, first chip contact plugs C1, first chip lines M1, and a first interlayer insulating layer IL1. The first shallow isolation parts ST1 may be disposed in a front surface of the first substrate SB1 and may define active regions for the first peripheral transistors PTR1. The first peripheral transistors PTR1, the first chip contact plugs C1, and the first chip lines M1 may be disposed on the front surface of the first substrate SB1, and the first interlayer insulating layer IL1 may cover the front surface of the first substrate SB1. The first substrate SB1 may include a semiconductive material. For example, the first substrate SB1 may be, for example, a single-crystalline silicon wafer, a silicon epitaxial layer, or a silicon-on-insulator (SOI) substrate. The first interlayer insulating layer IL1 may have a single-layer or multi-layer structure of an insulator, such as at least one of silicon oxide, silicon nitride, silicon oxynitride, SiOCH, a low dielectric constant material, a porous insulator, and/or the like.

The first peripheral transistors PTR1, the first chip contact plugs C1, and the first chip lines M1 may constitute logic circuits (Logic of FIG. 4A). The logic circuits may include, for example, a row driver, a row decoder, a column decoder, a timing generator, a correlated double sampler (CDS), an analog-to-digital converter (ADC), an I/O buffer, and/or the like.

An upper surface of the first semiconductor chip CH1 is bonded to a lower surface of the second semiconductor chip CH2. The first semiconductor chip CH1 may be electrically connected to the second semiconductor chip CH2 by fifth and sixth connection pads CP5 and CP6 (see FIG. 4A). For example, the fifth connection pad CP5 may be located at an upper end of the first interlayer insulating layer IL1; and the sixth connection pad CP6 may be located at a lower end of the second semiconductor chip CH2. In these cases, the first semiconductor chip CH1 may be bonded to the second semiconductor chip CH2 using, e.g., a metal-to-metal (e.g., Cu—Cu) bonding. Alternatively, the first semiconductor chip CH1 may be electrically connected to the second semiconductor chip CH2 by a through electrode.

The second semiconductor chip CH2 may transmit an electrical signal and/or charges generated in light-receiving regions PX of the third semiconductor chip CH3 (e.g., in response to light) to the first semiconductor chip CH1. The second semiconductor chip CH2 includes a lower insulating layer BL, a second substrate SB2, a second shallow isolation part ST2, driving transistors RX, DCX, SFX, and SLX (see FIG. 4A), second chip contact plugs C21 to C26 and C31 to C34, second chip lines FC1 and M2, a second interlayer insulating layer IL2, first connection pads CP1, third connection pads CP3, etc.

The second substrate SB2 may be, for example, a semiconductor substrate, such as a single-crystalline silicon wafer, a silicon epitaxial layer, a silicon-on-insulator (SOI) substrate, and/or the like. The lower insulating layer BL and the second interlayer insulating layer IL2 may each have a single-layer or multi-layer structure of an insulator, such as at least one of silicon oxide, silicon nitride, silicon oxynitride, SiCN, SiOCH, a low dielectric constant material, or porous insulator. A rear surface of the second substrate SB2 may be covered with the lower insulating layer BL. A lower surface of the lower insulating layer BL is in contact with an upper surface of the first interlayer insulating layer IL1.

Second shallow isolation parts ST2 are disposed on an upper surface of the second substrate SB2 and define active regions for a plurality of driving transistors RX, DCX, SFX, and SLX (see FIG. 4A). The plurality of driving transistors RX, DCX, SFX, and SLX may include a reset transistor RX, a dual conversion gain transistor DCX, a source follower transistor SFX, and a selection transistor SLX. The upper surface of the second substrate SB2 may be covered with the second interlayer insulating layer IL2. The first and third connection pads CP1 and CP3 are disposed at an upper end of the second interlayer insulating layer IL2.

The third semiconductor chip CH3 may be a light sensing chip. The third semiconductor chip CH3 includes a third substrate SB3 and a third interlayer insulating layer IL3. A deep isolation part 10 may be disposed in the third substrate SB3 and isolate the light-receiving regions PX. A front surface of the third substrate SB3 faces the second semiconductor chip CH2. Third shallow isolation parts ST3 are disposed in a front surface SB3_F of the third substrate SB3 and define active regions for transfer transistors TX (see FIG. 4A). The transfer transistors TX are disposed on the front surface SB3_F of the third substrate SB3. A connection relationship between the transfer transistors TX and the plurality of driving transistors RX, DCX, SFX, and SLX may be the same as that shown in FIG. 4A.

The front surface SB3_F of the third substrate SB3 is covered with the third interlayer insulating layer IL3. Third chip contact plugs C41, C42, and C5 and third chip lines FC2 and M4 are disposed in the third interlayer insulating layer IL3. Second and fourth connection pads CP2 and CP4 are disposed at a lower end of the third interlayer insulating layer IL3. A color filter CF and a microlens ML may be sequentially stacked on a rear surface SB3_B of the third substrate SB3.

Specifically, a plane of the second semiconductor chip CH2 will be described with reference to FIG. 1. The second substrate SB2 may be doped with impurities having a first conductive type. The first conductive type may be, for example, a P-type, and impurities having the first conductive type may be, for example, boron. A second shallow isolation part ST2 may be disposed on the second substrate SB2 and define first and second active regions ACT1 and ACT2 spaced apart from each other. The second shallow isolation part ST2 may have a single-layer or multi-layer structure of an insulator material such as at least one of silicon oxide, silicon nitride, or silicon oxynitride.

A first ground region GN1 is disposed in the second active region ACT2. The first ground region GN1 may be doped with impurities having the first conductive type. A concentration of impurities having the first conductive type with which the first ground region GN1 is doped may be higher than a concentration of impurities having the first conductive type with which (e.g., a bulk and/or remainder of) the second substrate SB2 is doped.

A selection gate electrode SEL, a source follower gate electrode SF, a reset gate electrode RG, and a dual conversion gain gate electrode DCG may be arranged in a line on the first active region ACT1. The selection gate electrode SEL, the source follower gate electrode SF, and the reset gate electrode RG may be disposed on a straight line along a second direction X2. A length of the source follower gate electrode SF in a second direction X2 may be greater than a length of each of the selection gate electrode SEL, the reset gate electrode RG, and the dual conversion gain gate electrode DCG in the second direction X2. Accordingly, noise of the source follower transistor SFX may be reduced.

Each of the selection gate electrode SEL, the source follower gate electrode SF, the reset gate electrode RG, and the dual conversion gain gate electrode DCG may be formed in a planar type or a vertical type. Alternatively, each of the driving transistors RX, DCX, SFX, and SLX including the gate electrodes may have a form of a fin field effect transistor (FinFET), a gate-all-around FET (GAAFET), a vertical transport field effect transistor (VFET), a vertical channel transistor (VCT), a buried channel array transistor (BCAT), or a multi-bridge channel FET (MBCFET).

Impurity regions may be disposed on two sides of each of the selection gate electrode SEL, the source follower gate electrode SF, the reset gate electrode RG, and the dual conversion gain gate electrode DCG in the first active region ACT1. The Impurity regions may become source/drain regions. The source/drain regions may be doped with impurities having a second conductive type opposite to the first conductive type. The second conductive type may be, for example, an N-type, and impurities having the second conductive type may be, for example, phosphorus or arsenic. The first ground region GN1 may be disposed to be adjacent to a right side of the first active region ACT1.

The first active region ACT1 may have a plurality of bent regions in a plan view. The dual conversion gain gate electrode DCG may be disposed adjacent to an end portion of the first active region ACT1. An impurity region on one side of the dual conversion gain gate electrode DCG may be referred to as a first floating diffusion region F1. An impurity region between the selection gate electrode SEL and the source follower gate electrode SF may be referred to as a first source region S1 of the source follower transistor SFX (see FIG. 4A). An impurity region between the source follower gate electrode SF and the reset gate electrode RG may be referred to as a first drain region D1 of the source follower transistor SFX. A power voltage Vpix of FIG. 4A may be applied to the first drain region D1.

The first floating diffusion region F1 may be adjacent to the first source region S1 in the first direction X1. In a plan view, the first source region S1 may surround the first floating diffusion region F1. For example, in a plan view, the first source region S1 may include a main portion SM adjacent to one side of the source follower gate electrode SF and a protrusion SP protruding from a sidewall of the main portion SM toward the first floating diffusion region F1. The protrusion SP may surround the first floating diffusion region F1. The protrusion SP may have an L-shape in a plan view. The protrusion SP may be located between the first ground region GN1 and the first floating diffusion region F1. As described above, the first source region S1 has a shape surrounding the first floating diffusion region F1. The first source region S1 having such a shape may serve to shield the first floating diffusion region F1 from a peripheral conductive structure.

Each of the first source region S1 and the first floating diffusion region F1 may be doped with impurities having the second conductive type. A concentration of impurities having the second conductive type with which the first source region S1 is doped may be the same as or different from a concentration of impurities having the second conductive type with which the first floating diffusion region F1 is doped.

A twenty second contact plug C22 and a twenty third contact plug C23 may be disposed on the first source region S1. The twenty second contact plug C22 may be located on the main portion SM of the first source region S1, and the twenty third contact plug C23 may be located on the protrusion SP. The twenty second contact plug C22 and the twenty third contact plug C23 may be connected by a second line M2.

The first floating diffusion region F1 may be electrically connected to the source follower gate electrode SF. A twenty first contact plug C21 is disposed on the first floating diffusion region F1. A thirty first contact plug C31 is disposed on the source follower gate electrode SF. A first FD connection line FC1 connects the twenty first contact plug C21 to the thirty first contact plug C31. The first FD connection line FC1 may have a shape of a bar extending in the first direction X1 in a plan view. FD in the first FD connection line FC1 may mean floating diffusion. The first FD connection line FC1 may be located at the same level as the second line M2.

Effective capacitance CFD in the first floating diffusion region F1 may be expressed by Equation 1 below according to a Miller effect.

C_{FD}=Cgs(1−Av) <Equation 1>

In Equation 1, Cgs may be a physical capacitance between the first floating diffusion region F1 and the first source region S1. Av may correspond to gain of a source follower gate electrode. According to Equation 1, since Av, which is gain of a source follower gate electrode, is subtracted from 1, effective capacitance C_{FD} in the first floating diffusion region F1 may become smaller than the physical capacitance Cgs between the first floating diffusion region F1 and the first source region S1. That is, parasitic capacitances between the first floating diffusion region F1 and peripheral conductive structures may be reduced due to the Miller effect. Accordingly, conversion gain of the first floating diffusion region F1 may be improved, and noise may be reduced. Thus, a clear image may be realized.

A twenty fourth contact plug C24 may be disposed on the first drain region D1, and the power voltage Vpix of FIG. 4A may be applied to the twenty fourth contact plug C24. A twenty sixth contact plug C26 may be disposed on an impurity region on one side of the selection gate electrode SEL. The twenty sixth contact plug C26 may be connected to a logic circuit of the first semiconductor chip CH1. A twenty fifth contact plug C25 may be disposed on the first ground region GN1. A ground voltage may be applied to the first ground region GN1 through the twenty fifth contact plug C25.

A thirty second contact plug C32 may be disposed on the dual conversion gain gate electrode DCG. A thirty third contact plug C33 may be disposed on the reset gate electrode RG. A thirty fourth contact plug C34 may be disposed on the selection gate electrode SEL.

The twenty second contact plug C22 and the twenty third contact plug C23 connected to the first source region S1 may be disposed at places adjacent to two sidewalls of the twenty first contact plug C21 connected to the first floating diffusion region F1. The twenty third contact plug C23 may be located between the twenty first contact plug C21 and the twenty fifth contact plug C25. The twenty second contact plug C22 may be located between the twenty first contact plug C21 and the twenty fourth contact plug C24 and/or between the twenty first contact plug C21 and the twenty sixth contact plug C26. Accordingly, parasitic capacitances between the twenty first contact plug C21 and other peripheral contact plugs C24, C25, C26, etc. may be reduced due to the Miller effect. Accordingly, conversion gain of the first floating diffusion region F1 may be improved, and noise may be reduced. Thus, a clear image may be realized.

The third substrate SB3 may be doped with impurities having a first conductive type. The first conductive type may be, for example, a P-type, and impurities having the first conductive type may be, for example, boron. The deep isolation part 10 may be disposed in the third substrate SB3 and isolate the light-receiving regions PX. The deep isolation part 10 may penetrate the third substrate SB3. The deep isolation part 10 may include an insulating pattern. The insulating pattern may have a single-layer or multi-layer structure of an insulator material, such as at least one of silicon oxide, silicon nitride, or a metal oxide. The deep isolation part 10 may further include a conductive pattern disposed inside the insulating pattern.

The light-receiving regions PX may be two-dimensionally arranged along the first horizontal direction X1 and the second horizontal direction X2 intersecting each other. The light-receiving regions PX in a 2×2 array adjacent to each other may constitute one group region GRP. The one group region GRP may include first to fourth light-receiving regions PX(1) to PX(4) arranged along a clockwise direction. The light-receiving regions PX may each include a left side sub region SPL and a right side sub region SPR. In a plan view, a portion of the deep isolation part 10 may be inserted between the left side sub region SPL and the right side sub region SPR. The deep isolation part 10 does not completely isolate the left side sub region SPL from the right side sub region SPR. Accordingly, an end portion of the left side sub region SPL may be connected to an end portion of the right side sub region SPR.

A photoelectric conversion part PD may be disposed in each of the left side sub region SPL and the right side sub region SPR in the third substrate SB3. The photoelectric conversion part PD may be doped with impurities having the second conductive type (for example, N-type phosphorus or arsenic). The photoelectric conversion part PD and impurities (for example, P-type boron) which have the first conductive type and with which the third substrate SB3 is doped may form a PN junction.

A third shallow isolation part ST3 may be disposed in each of the left side sub region SPL and the right side sub region SPR in the front surface SB3_F of the third substrate SB3, and third to fifth active regions ACT3 to ACT5 may be defined. The third active region ACT3 may have an L-shape or a shape in which a letter “L” is mirror symmetrical in the first direction X1 or the second direction X2 in a plan view. A transfer gate electrode TG may be disposed in the third active region ACT3. The transfer gate electrode TG may be a vertical type. Alternatively, the transfer gate electrode TG may be a planar type having a flat shape without extending into the first substrate SB1. The transfer gate electrode TG may be formed of a conductive material. For example, the transfer gate electrode TG may be formed of polysilicon doped with impurities. Sidewalls of the transfer gate electrode TG may be covered with a spacer 12. The spacer 12 may have a single-layer or multi-layer structure of an insulator material, such as at least one of silicon nitride or silicon oxide.

A left side transfer gate electrode TG(L) may be disposed in the left side sub region SPL. A right side transfer gate electrode TG(R) may be disposed in the right side sub region SPR. A second floating diffusion region F2 may be disposed on one side of the transfer gate electrode TG in the third active region ACT3. The second floating diffusion region F2 may be vertically spaced apart from the photoelectric conversion part PD. The second floating diffusion region F2 may be doped with impurities having the second conductive type.

The fourth active region ACT4 may be spaced apart from the third active region ACT3 in the second direction X2. A second ground region GN2 may be disposed in the fourth active region ACT4. The second ground region GN2 may be doped with impurities having the first conductive type, and a concentration of impurities having the first conductive type with which the second ground region GN2 is doped may be higher than a concentration of impurities having the first conductive type with which the third substrate SB3 is doped.

The fifth active region ACT5 may be disposed between the second floating diffusion region F2 of an end portion of the left side sub region SPL and the second floating diffusion region F2 of an end portion of the right side sub region SPR. A second source region S2 may be disposed in the fifth active region ACT5. The left side sub region SPL and the right side sub region SPR may share one second source region S2. One second source region S2 may be disposed in one light-receiving region PX. Accordingly, four second source regions S2 may be disposed in one group region GRP.

The second source region S2 may be doped with impurities having the second conductive type. The second source region S2 may be electrically connected to the first source region S1. The second floating diffusion regions F2 are electrically connected to the first floating diffusion region F1. A concentration of impurities having the second conductive type with which the second source region S2 is doped may be the same as or different from a concentration of impurities having the second conductive type with which the second floating diffusion region F2 is doped.

In a plan view, in one group region GRP, at least a portion of the second floating diffusion regions F2 is surrounded by the second source regions S2. Accordingly, parasitic capacitances between the second floating diffusion regions F2 and other peripheral conductive structures may be reduced due to the Miller effect. Accordingly, conversion gain of the second floating diffusion regions F2 may be improved, and noise may be reduced. Thus, a clear image may be realized.

The second floating diffusion regions F2 may be respectively in contact with forty first contact plugs C41. In one group region GRP, the forty first contact plugs C41 may be connected by a second FD connection line FC2. FD in the second FD connection line FC2 may mean floating diffusion. A fifth contact plug C5 may be disposed at the center of the second FD connection line FC2. The fifth contact plug C5 may connect the second FD connection line FC2 to a fourth connection pad CP4. The forty first contact plugs C41, the second FD connection line FC2, the fifth contact plug C5, and the fourth connection pad CP4 may be electrically connected to the first floating diffusion region F1.

The second source regions S2 may be respectively in contact with forty second contact plugs C42. The forty second contact plugs C42 may be connected to a fourth line M4. The fourth line M4 may be connected to a second connection pad CP2. The forty second contact plugs C42, the fourth line M4, and the second connection pad CP2 may be electrically connected to the first source region S1. The fourth line M4 may be located at the same level as the second FD connection line FC2.

The forty second contact plugs C42 may be disposed around the forty first contact plugs C41 and reduce a parasitic capacitance between the forty first contact plugs C41 and a peripheral conductive structure. The fourth line M4 may be disposed around the second FD connection line FC2 and reduce a parasitic capacitance between the second FD connection line FC2 and a peripheral conductive structure. The second connection pad CP2 may be disposed around the fourth connection pad CP4 and reduce a parasitic capacitance between the fourth connection pad CP4 and a peripheral conductive structure.

A gate insulating layer Gox may be interposed between transfer gate electrodes TG and the third substrate SB3. The contact plugs C1, C21 to C26, C31 to C34, C41, C42, and C5, the lines M1, FC1, M2, FC2, and M4, and the connection pads CP1 to CP6 may each include conductive material such as a metal (such as aluminum, copper, tungsten, titanium, and tantalum). The interlayer insulating layers IL1 to IL3 may each have a single-layer or multi-layer structure of an insulator material, such as at least one of silicon oxide, silicon nitride, silicon oxynitride, SiCN, SiOCN, a low dielectric constant material, or porous insulator.

The rear surface SB3_B of the third substrate SB3 may be covered with a fixed charge layer FL. The fixed charge layer FL may have a negative fixed charge. The fixed charge layer FL may be formed of a metal fluoride and/or metal oxide including at least one metal selected from the group consisting of hafnium (Hf), zirconium (Zr), aluminum (Al), tantalum (Ta), titanium (Ti), yttrium, and lanthanoid. For example, the fixed charge layer FL may be a hafnium oxide layer or an aluminum oxide layer. Here, hole accumulation may occur around the fixed charge layer FL. Accordingly, dark current generation and a white spot may be effectively reduced.

A grid pattern WG may be disposed on the fixed charge layer FL. The grid pattern WG may include, for example, at least one of titanium, titanium nitride, or tungsten. The color filter CF may be disposed between grid patterns WG. One group region GRP may be covered with one color filter CF. The color filter CF may have a blue, green, or red color. Alternatively, the color filter CF may have a cyan, magenta, or yellow color. Alternatively, the color filter CF may be colorless. When the color filter CF is colorless, the color filter CF may be a part of the microlens ML. The color filter CF may be provided in plurality, and the color filters CF may be two-dimensionally arranged along the first direction X1 and the second direction X2. The color filter CF may have a form of a bayer pattern, a 2×2 tetra pattern, a 3×3 nona pattern, or a 4×4 hexadeca pattern.

The microlens ML may be disposed on the color filter CF. One microlens ML may cover one group region GRP. The microlens ML may be provided in plurality, and the microlenses ML may be two-dimensionally arranged along the first direction X1 and the second direction X2.

In the image sensor 100 according at least some embodiments, four light-receiving regions PX (or eight sub regions SPL and SPR) adjacent to each other may share the plurality of driving transistors RX, DCX, SFX, and SLX. The image sensor 100 may be a backside-illuminated image sensor. Light may be incident into the third substrate SB3 through the rear surface SB3_B of the third substrate SB3. Electron-hole pairs may be generated in the PN junction by incident light. Such generated electrons may move to the photoelectric conversion part PD. When a voltage is applied to the transfer gate electrode TG, the electrons may move to the first and second floating diffusion regions F1 and F2 and be accumulated. A bias of the gate electrode SF of the source follower transistor SFX is changed in proportion to the amount of accumulated electrons to cause a change in potential of the first source region S1 of the source follower transistor SFX. Here, when the selection transistor SLX is turned on, an electrical signal may be output to a logic circuit of the first semiconductor chip CH1.

The reset transistor RX may periodically reset electrons accumulated in the first and second floating diffusion regions F1 and F2. Conversion gain of light-receiving region PX may be variable according to on/off of the dual conversion gain transistor DCX. Thus, a clear image having improved high dynamic range (HDR) characteristics may be realized.

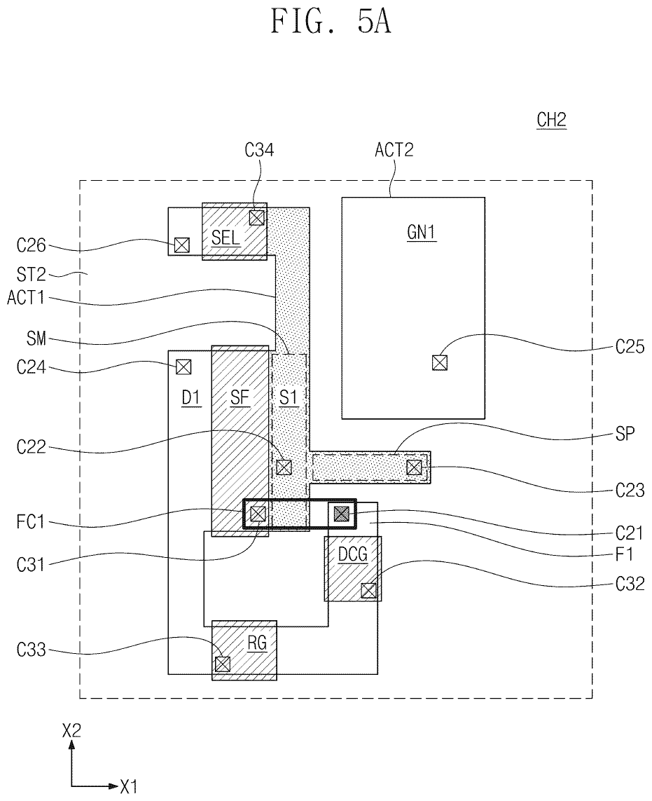

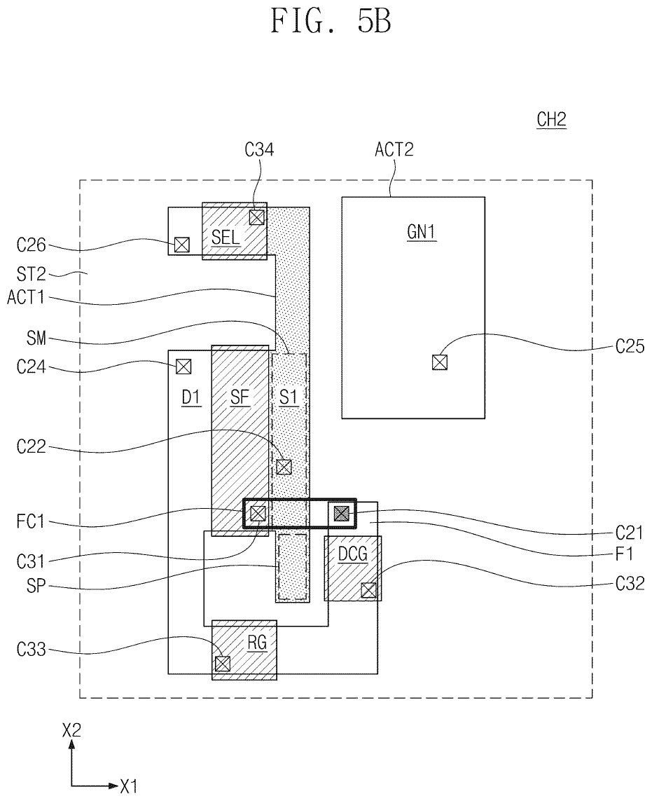

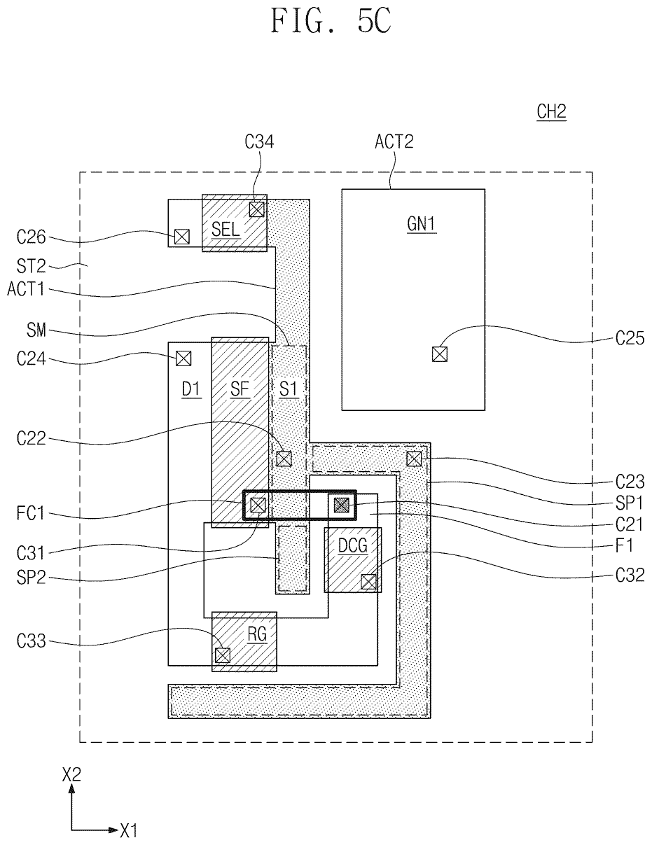

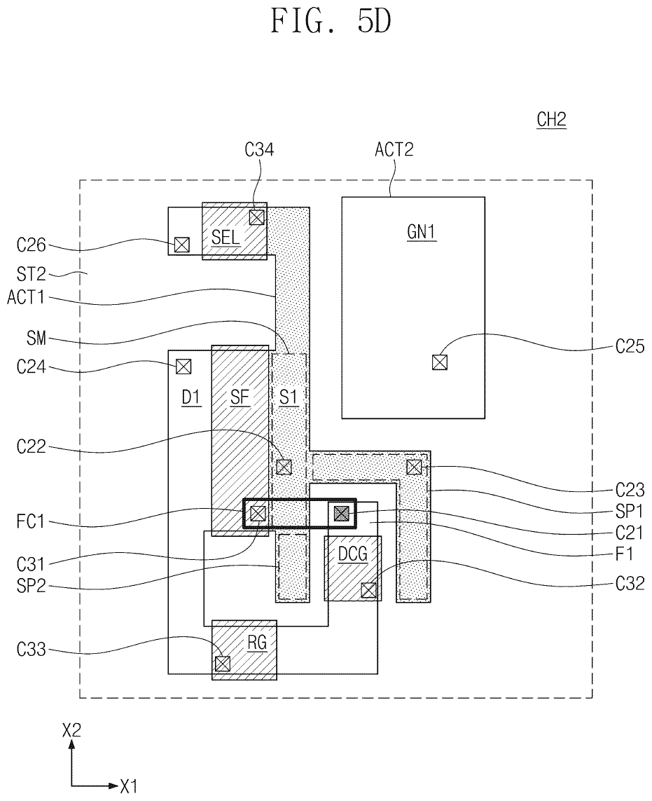

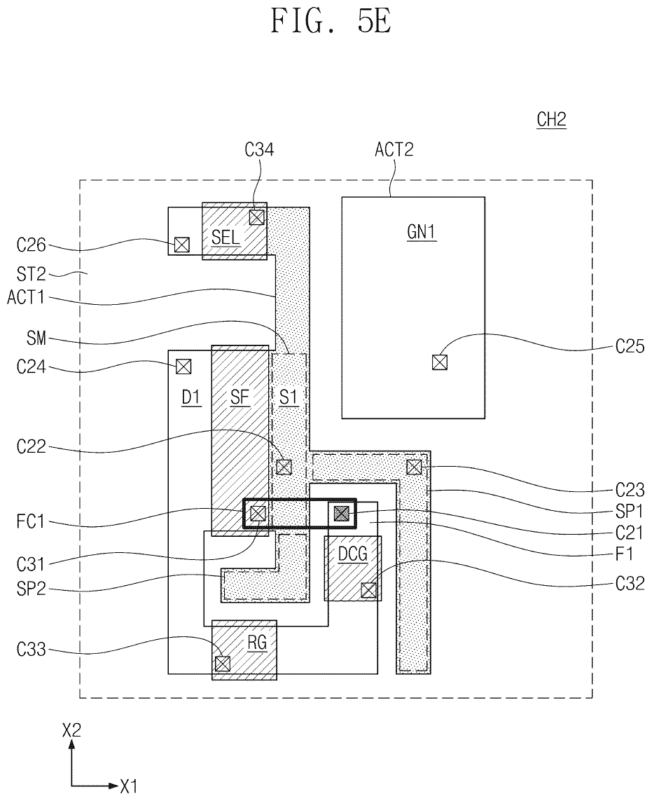

FIGS. 5A to 5E are plan views of a second semiconductor chip of an image sensor according to embodiments of the inventive concepts.

Referring to FIG. 5A, in a plan view, the protrusion SP of the first source region S1 may have a shape of a bar extending from a side surface of the main portion SM in the first direction X1. The protrusion SP of the first source region S1 may be interposed between the first ground region GN1 and the first floating diffusion region F1. Other configurations may be the same as/similar to those described with reference to FIG. 1.

Referring to FIG. 5B, in a plan view, the protrusion SP of the first source region S1 may have a shape of a bar extending from a side surface of the main portion SM in the second direction X2. The protrusion SP of the first source region S1 may be interposed between the first drain region D1 and the dual conversion gain gate electrode DCG. Other configurations may be the same as/similar to those described with reference to FIG. 1.

Referring to FIG. 5C, in a plan view, the first source region S1 may include two protrusions SP1 and SP2 protruding from the main portion SM. A first protrusion SP1 may protrude from one sidewall of the main portion SM in the first direction X1 and may be interposed between the first floating diffusion region F1 and the first ground region GN1 and may be adjacent to a right side of the first floating diffusion region F1. The first protrusion SP1 may have a C-shape in a plan view. A second protrusion SP2 may protrude from another sidewall of the main portion SM in the second direction X2, may be adjacent to a left side of the first floating diffusion region F1 and may be interposed between the dual conversion gain gate electrode DCG and the first drain region D1. The second protrusion SP2 may have an L-shape in a plan view. Other configurations may be the same as/similar to those described with reference to FIG. 1.

Referring to FIG. 5D, the first protrusion SP1 may have an L-shape in a plan view. The second protrusion SP2 may have a bar shape in a plan view. Other configurations may be the same as/similar to those described with reference to FIG. 5C.

Referring to FIG. 5E, the first protrusion SP1 may have an L-shape in a plan view. The second protrusion SP2 may have an L-shape in a plan view. Other configurations may be the same as/similar to those described with reference to FIG. 5C.

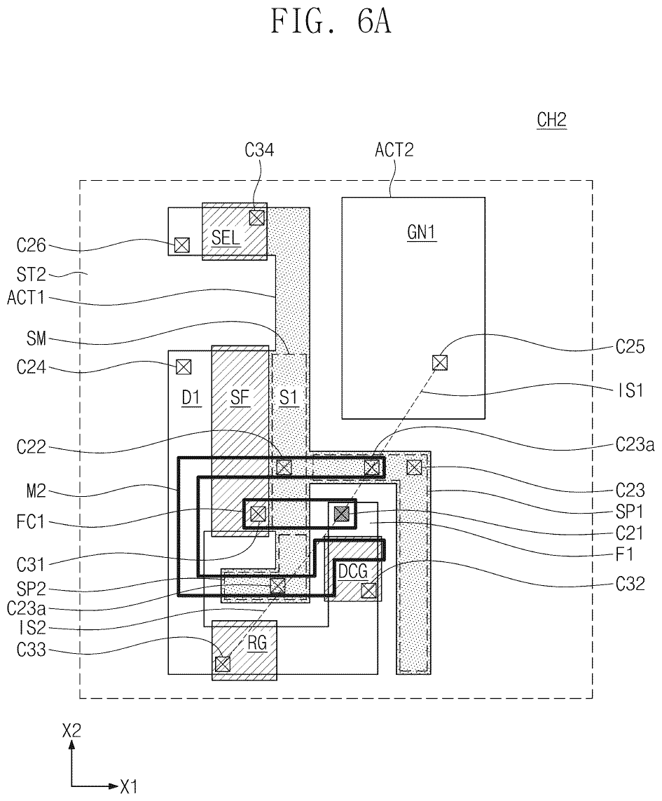

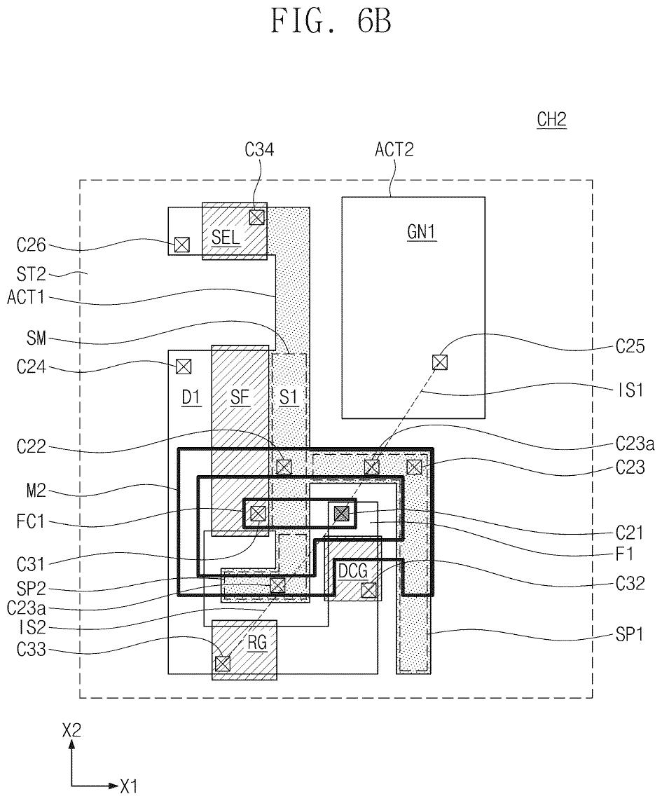

FIGS. 6A and 6B are plan views of a second semiconductor chip of an image sensor according to embodiments of the inventive concepts.

Referring to FIG. 6A, the second line M2 connected to the first source region S1 may have a C-shape in which the first FD connection line FC1 is surrounded in a plan view. The second line M2 may be connected to the twenty second and twenty third contact plugs C22 and C23. A portion of the second line M2 may traverse the source follower gate electrode SF. Another portion of the second line M2 may overlap the dual conversion gain gate electrode DCG. Since the second line M2 has a C-shape in which the first FD connection line FC1 is surrounded, conversion gain of the first floating diffusion region F1 may be improved, and noise may be reduced.

The second semiconductor chip CH2 according to at least some embodiments may further include auxiliary contact plugs C23a connecting the second line M2 to the first source region S1. One of the auxiliary contact plugs C23a may be located between the twenty fifth contact plug C25 on the first ground region GN1 and the twenty first contact plug C21 on the first floating diffusion region F1. The one of the auxiliary contact plugs C23a, the twenty fifth contact plug C25, and the first floating diffusion region F1 may be located on a first virtual straight line IS1. Another one of the auxiliary contact plugs C23a may be located between the thirty third contact plug C33 on the reset gate electrode RG and the twenty first contact plug C21 on the first floating diffusion region F1. The other one of the auxiliary contact plugs C23a, the thirty third contact plug C33, and the first floating diffusion region F1 may be located on a second virtual straight line IS2. According to the inventive concepts, the auxiliary contact plugs C23a may be additionally disposed as described above, thereby improving conversion gain of the first floating diffusion region F1 and reducing noise. Other structures may be the same as/similar to those described with reference to FIG. 5E.

Alternatively, referring to FIG. 6B, the second line M2 connected to the first source region S1 may have a shape of a closed curve surrounding the first FD connection line FC1 in a plan view. Other structures may be the same as/similar to those described with reference to FIG. 6A.

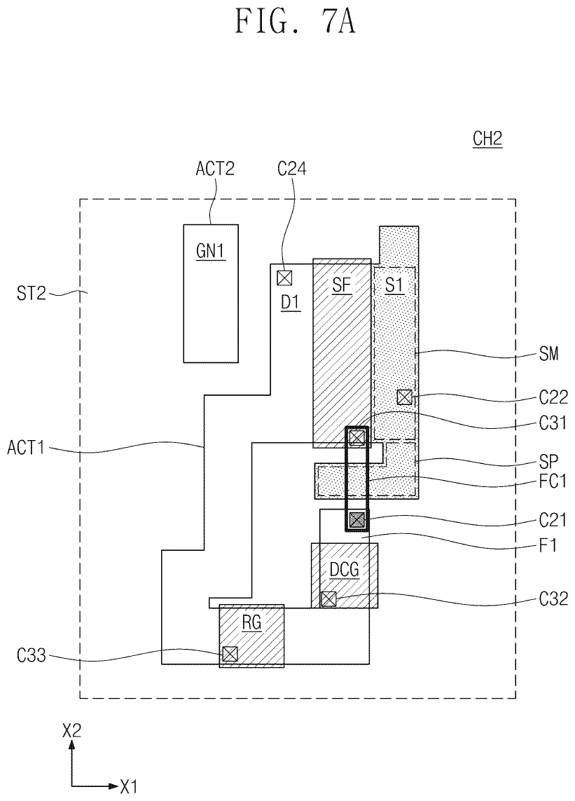

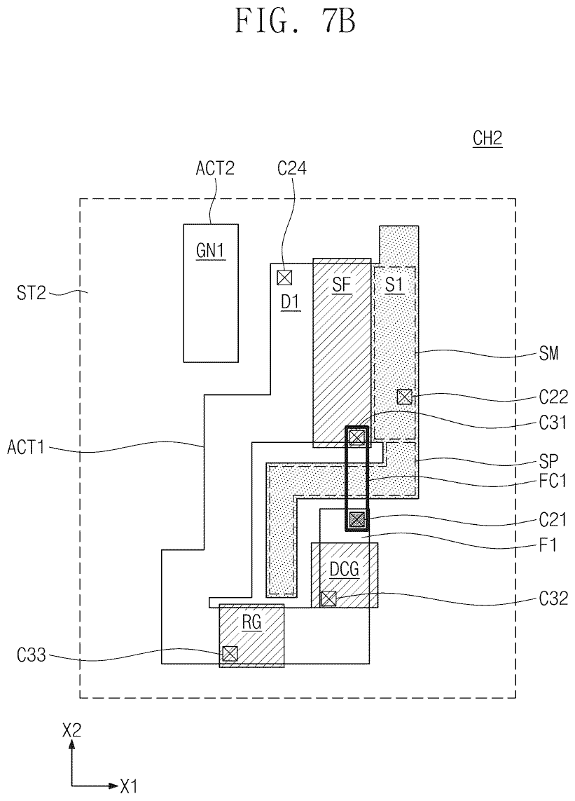

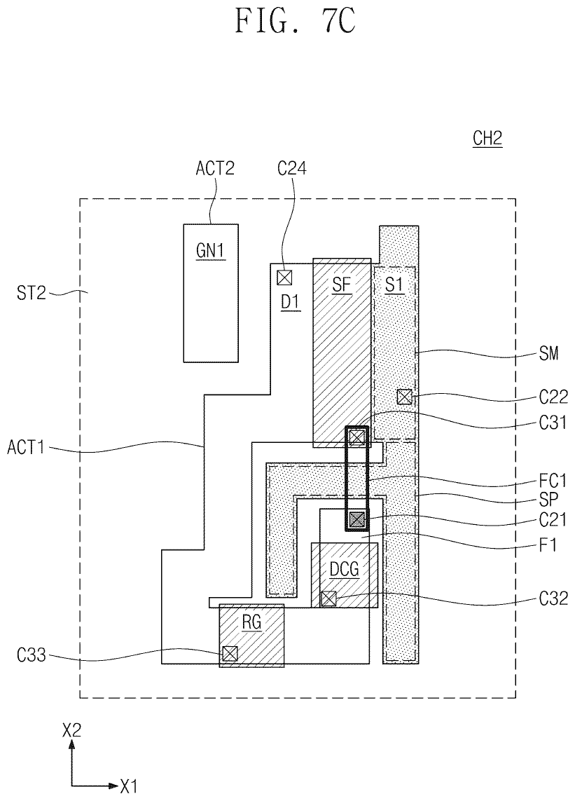

FIGS. 7A to 7C are plan views of a second semiconductor chip of an image sensor according to embodiments of the inventive concepts.

Referring to FIG. 7A, in the second semiconductor chip CH2 according to at least some embodiments, the first ground region GN1 may be disposed on a left side of the first active region ACT1. Additionally, a shape of the first active region ACT1 of FIG. 7A may be different from that of FIG. 1. The first active region ACT1 may have a structure similar to a C-shape in a plan view. The source follower gate electrode SF, the reset gate electrode RG, and the dual conversion gain gate electrode DCG may be arranged in a line on the first active region ACT1. The dual conversion gain gate electrode DCG may be disposed to be adjacent to an end portion of the first active region ACT1. The first floating diffusion region F1 is disposed on one side of the dual conversion gain gate electrode DCG. The first floating diffusion region F1 may be adjacent to the source follower gate electrode SF in the second direction X2. The first FD connection line FC1 may connect the first floating diffusion region F1 to the source follower gate electrode SF. The first FD connection line FC1 may have a shape of a bar elongated in the second direction X2.

The first source region S1 is disposed on one side of the source follower gate electrode SF. In a plan view, the first source region S1 may have the main portion SM and the protrusion SP. The protrusion SP may protrude from one side of the main portion SM in the second direction X2 and may be interposed between the source follower gate electrode SF and the first floating diffusion region F1. The protrusion SP may have an L-shape in a plan view. Other configurations may be the same as/similar to those described with reference to FIG. 1.

Referring to FIG. 7B, in the second semiconductor chip CH2 according at least some embodiments, the protrusion SP may further extend from the structure of FIG. 7A, may be located between the first drain region D1 and the dual conversion gain gate electrode DCG, and may be adjacent to the reset gate electrode RG. Other structures may be the same as/similar to those described with reference to FIG. 7A.

Referring to FIG. 7C, in the second semiconductor chip CH2 according at least some embodiments, a portion of the protrusion SP may further extend from the structure of FIG. 7B and may be adjacent to a right side of the dual conversion gain gate electrode DCG. In a plan view, the protrusion SP may have a C-shape in which the first floating diffusion region F1 is surrounded. Other structures may be the same as/similar to those described with reference to FIG. 7B.

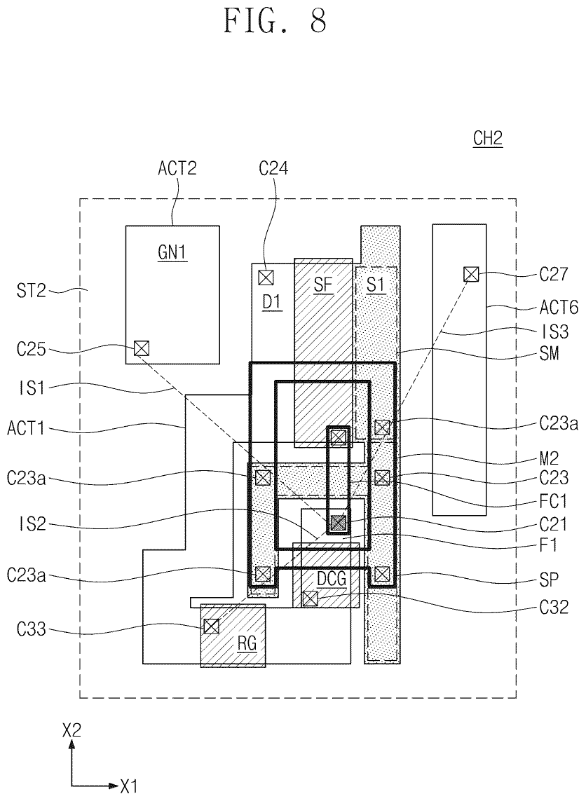

FIG. 8 is a plan view of a second semiconductor chip of an image sensor according to embodiments of the inventive concepts.

Referring to FIG. 8, the second semiconductor chip CH2 according at least some embodiments may further include a sixth active region ACT6 and a twenty seventh contact plug C27 disposed thereon. The sixth active region ACT6 may be disposed on a right side of the first active region ACT1. The sixth active region ACT6 may be doped with impurities having the second conductive type. The power voltage Vpix may be applied to the twenty seventh contact plug C27.

The second line M2 connected to the first source region S1 may have a shape of a closed curve surrounding the first FD connection line FC1 in a plan view. The second line M2 may be connected to the twenty second and twenty third contact plugs C22 and C23. A portion of the second line M2 may traverse the source follower gate electrode SF. Another portion of the second line M2 may traverse the dual conversion gain gate electrode DCG.

The second semiconductor chip CH2 according to at least some embodiments may further include auxiliary contact plugs C23a connecting the second line M2 to the first source region S1. One of the auxiliary contact plugs C23a may be located between the twenty fifth contact plug C25 on the first ground region GN1 and the twenty first contact plug C21 on the first floating diffusion region F1. The one of the auxiliary contact plugs C23a, the twenty fifth contact plug C25, and the first floating diffusion region F1 may be located on the first virtual straight line IS1.

Another one of the auxiliary contact plugs C23a may be located between the thirty third contact plug C33 on the reset gate electrode RG and the twenty first contact plug C21 on the first floating diffusion region F1. The other one of the auxiliary contact plugs C23a, the thirty third contact plug C33, and the first floating diffusion region F1 may be located on the second virtual straight line IS2.

Still another one of the auxiliary contact plugs C23a may be located between the twenty seventh contact plug C27 on the sixth active region ACT6 and the twenty first contact plug C21 on the first floating diffusion region F1. The still another one of the auxiliary contact plugs C23a, the twenty seventh contact plug C27, and the first floating diffusion region F1 may be located on a third virtual straight line IS3. Other structures may be the same as/similar to those described with reference to FIG. 7C.

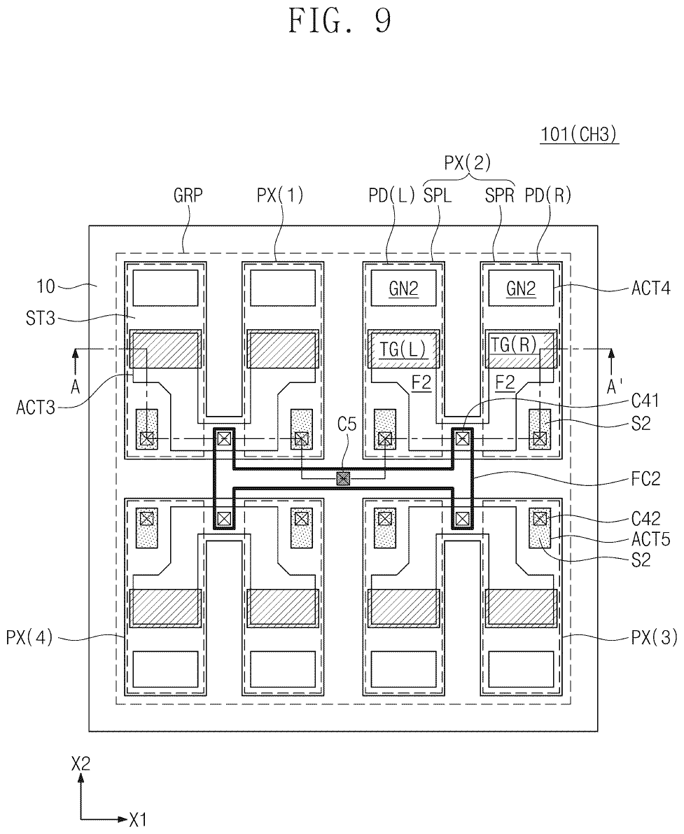

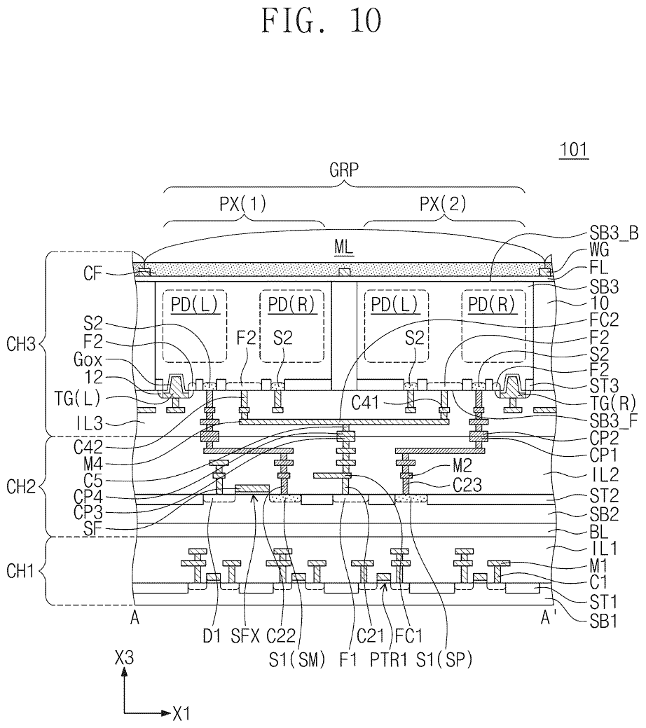

FIG. 9 is a plan view of a third semiconductor chip of an image sensor according to embodiments of the inventive concepts. FIG. 10 is a cross-sectional view taken along line A-A′ of FIG. 9 according to embodiments of the inventive concepts.

Referring to FIGS. 9 and 10, in the third semiconductor chip CH3 of an image sensor 101 according at least some embodiments, the third active region ACT3 has a shape in which the third active regions ACT3 are mirror symmetrical and connected to each other in the sub regions SPL and SPR of FIG. 2. Accordingly, in one light-receiving region PX, the third active region ACT3 according at least some embodiments may have a U-shape in a plan view. In one light-receiving region PX, the second floating diffusion region F2 next to the left side transfer gate electrode TG(L) may be connected to the second floating diffusion region F2 next to the right side transfer gate electrode TG(R). A forty first contact plug C41 may be located, between left side and right side sub regions SPL and SPR, at the center of the second floating diffusion region F2. In one group region GRP, four forty first contact plugs C41 may be disposed. The second FD connection line FC2 may connect the forty first contact plugs C41. The second FD connection line FC2 may have an H-shape in a plan view.

Second source regions S2 may be respectively disposed in the left side and right side sub regions SPL and SPR. In one light-receiving region PX, two second source regions S2 may be disposed, and the second floating diffusion region F2 may be disposed between the second source regions S2. In one group region GRP, eight second source regions S2 may be disposed. The second source regions S2 may be electrically connected to the first source region S1. The second source regions S2 may be disposed around the second floating diffusion regions F2, thereby improving conversion gain of the second floating diffusion regions F2 and reducing noise.

The second semiconductor chip CH2 of the image sensor 101 according at least some embodiments may have one structure among those of FIGS. 1 and 5A to 8. In the image sensor 101 according at least some embodiments, four light-receiving regions PX (or eight sub regions SPL and SPR) adjacent to each other may share the driving transistors RX, DCX, SFX, and SLX. Other structures may be the same as/similar to those described with reference to FIGS. 1 to 8.

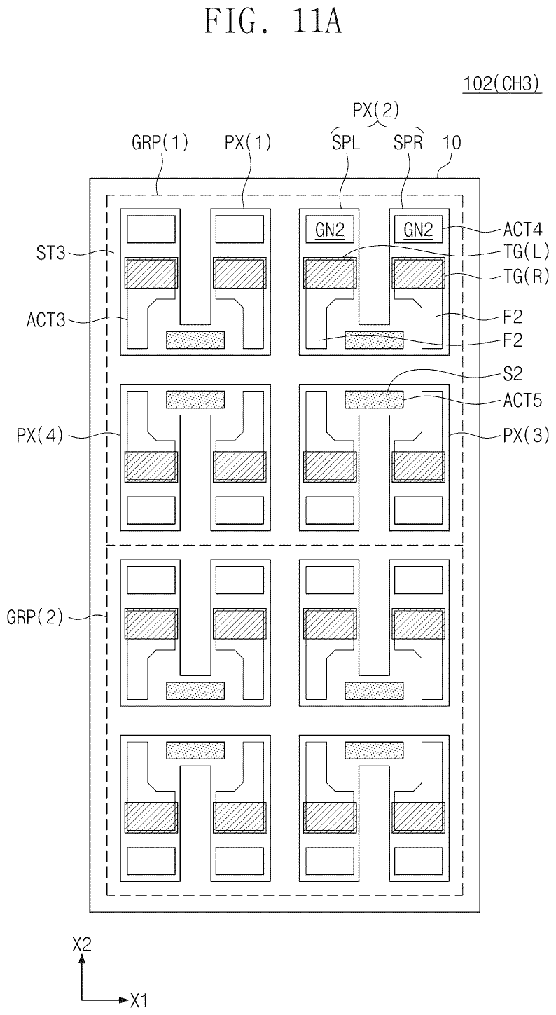

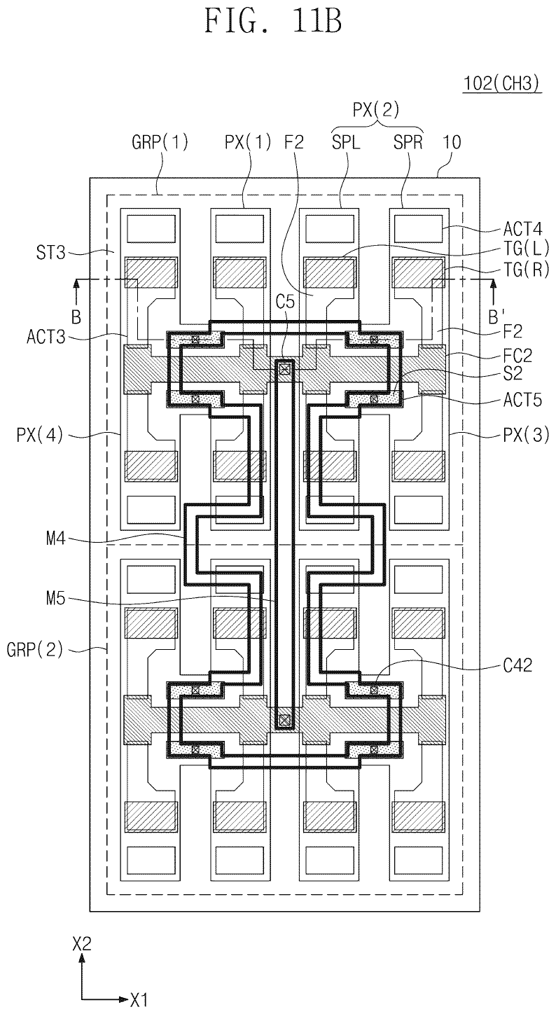

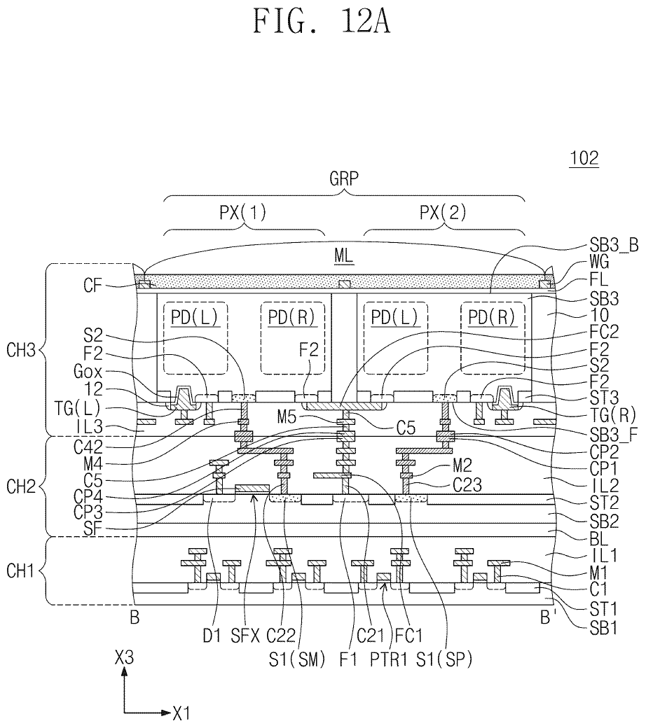

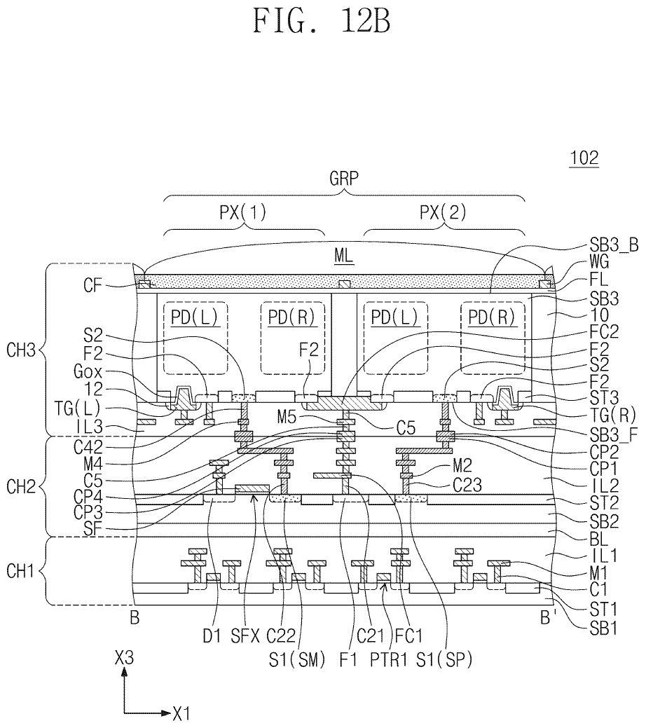

FIGS. 11A and 11B are plan views of a third semiconductor chip of an image sensor according to embodiments of the inventive concepts. FIGS. 12A and 12B are cross-sectional views taken along line B-B′ of FIG. 11B according to embodiments of the inventive concepts.

Referring to FIG. 11A, the third semiconductor chip CH3 of an image sensor 102 according at least some embodiments includes first and second group regions GRP(1) and GRP(2) arranged along the second direction X2. The first and second group regions GRP(1) and GRP(2) may each have the same layout as/a similar layout to the third semiconductor chip CH3 of FIG. 2.

Referring to FIGS. 11B, 12A, and 12B, the second FD connection line FC2 may extend in the first direction X1 and connect the second floating diffusion regions F2 of the light-receiving regions PX in each of the first and second group regions GRP(1) and GRP(2) in the structure of FIG. 11A. That is, one second FD connection line FC2 may traverse the center of the first group region GRP(1) in the first direction X1 and may be in contact with lower surfaces of the second floating diffusion regions F2 belonging to the first group region GRP(1). Another second FD connection line FC2 may traverse the center of the second group region GRP(2) in the first direction X1 and may be in contact with lower surfaces of the second floating diffusion regions F2 belonging to the second group region GRP(2).

Sidewalls of the second FD connection line FC2 may be covered with the spacer 12. In at least some embodiments, the second FD connection line FC2 may be formed of the same material as the transfer gate electrode TG. For example, the second FD connection line FC2 and the transfer gate electrode TG may be both formed of polysilicon and may be doped with impurities. The quantity of impurities may be the same and/or different. In these case, the second FD connection line FC2 and the transfer gate electrode TG may be referred to as having a same base material. As shown in FIG. 12A, an upper surface of the second FD connection line FC2 may be located at the same level as lower surfaces of the second floating diffusion regions F2. Alternatively, as shown in FIG. 12B, a portion of the second FD connection line FC2 may be inserted into the third shallow isolation part ST3 and the deep isolation part 10 and in contact with side surfaces of the second floating diffusion regions F2.

The second FD connection line FC2 is in contact with the fifth contact plug C5 at the center of the first group region GRP(1). The second FD connection line FC2 is in contact with the fifth contact plug C5 at the center of the second group region GRP(2). A fifth line M5 may connect the fifth contact plug C5 at the center of the first group region GRP(1) to the fifth contact plug C5 at the center of the second group region GRP(2). In a plan view, the fifth line M5 may have a shape of a bar or a line extending in the second direction X2.

The second source regions S2 of the first and second group regions GRP(1) and GRP(2) may be connected to the fourth line M4. A level of the fourth line M4 may be different from a level of the second FD connection line FC2. In a plan view, the fourth line M4 may surround the fifth line M5 as shown in FIG. 11B. Accordingly, conversion gain of the second floating diffusion regions F2 may be improved, and noise may be reduced.

The second semiconductor chip CH2 of the image sensor 102 according at least some embodiments may have one structure among those of FIGS. 1 and 5A to 8. In the image sensor 102 according at least some embodiments, the light-receiving regions PX of two group regions GRP(1) and GRP(2) adjacent to each other may share the driving transistors RX, DCX, SFX, and SLX. Other structures may be the same as/similar to those described with reference to FIGS. 1 to 8.

In the specification, a concept of individual semiconductor chips may be defined by a stacked structure formed by several semiconductor wafers which are different from each other. An interface between the semiconductor chips may not be definitely observed because of bonding shape, bonding method, or bonding material between the semiconductor chips, and the stacked structure having an ambiguous interface is not excluded from the concept of the individual semiconductor chips.

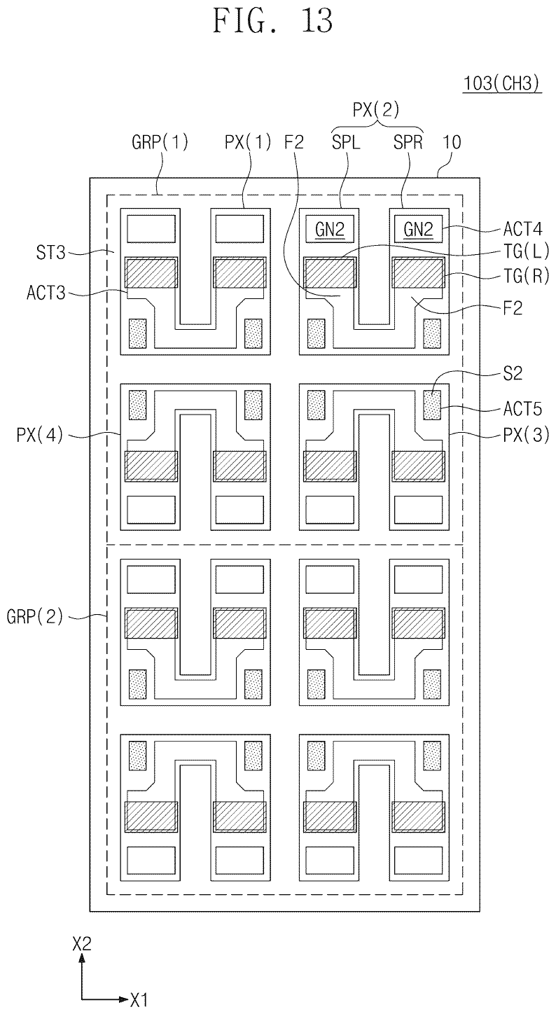

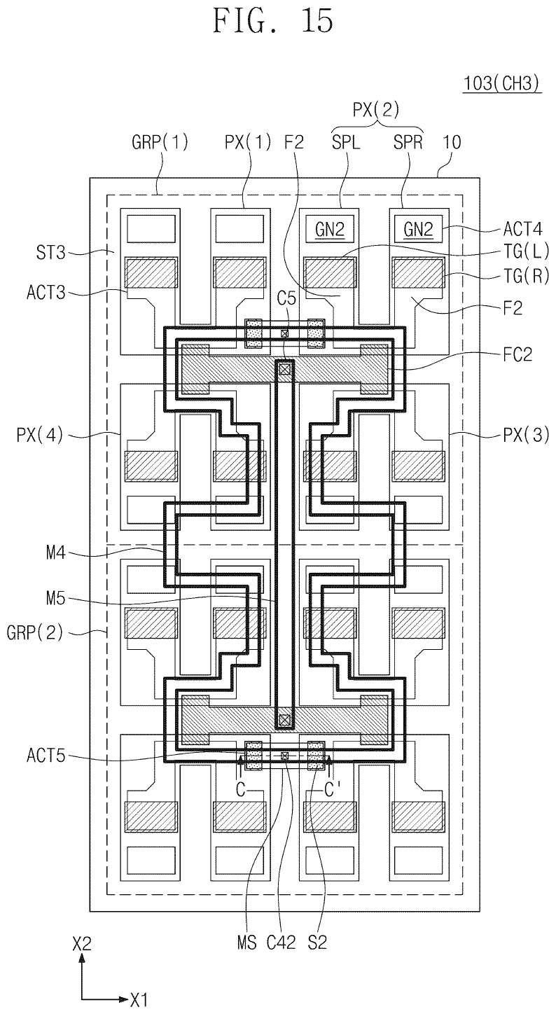

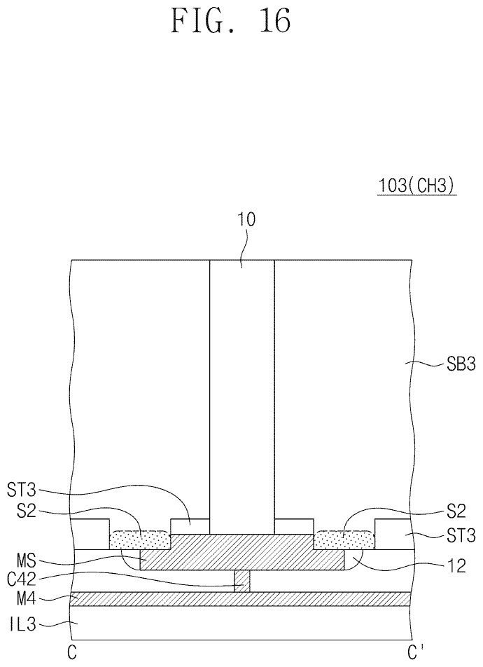

FIGS. 13 to 15 are plan views of a third semiconductor chip of an image sensor according to embodiments of the inventive concepts. FIG. 16 is a partial cross-sectional view taken along line C-C′ of FIG. 15 according to embodiments of the inventive concepts.

Referring to FIG. 13, the third semiconductor chip CH3 of an image sensor 103 according at least some embodiments includes the first and second group regions GRP(1) and GRP(2) arranged along the second direction X2. The first and second group regions GRP(1) and GRP(2) may each have the same layout as/a similar layout to the third semiconductor chip CH3 of FIG. 9.

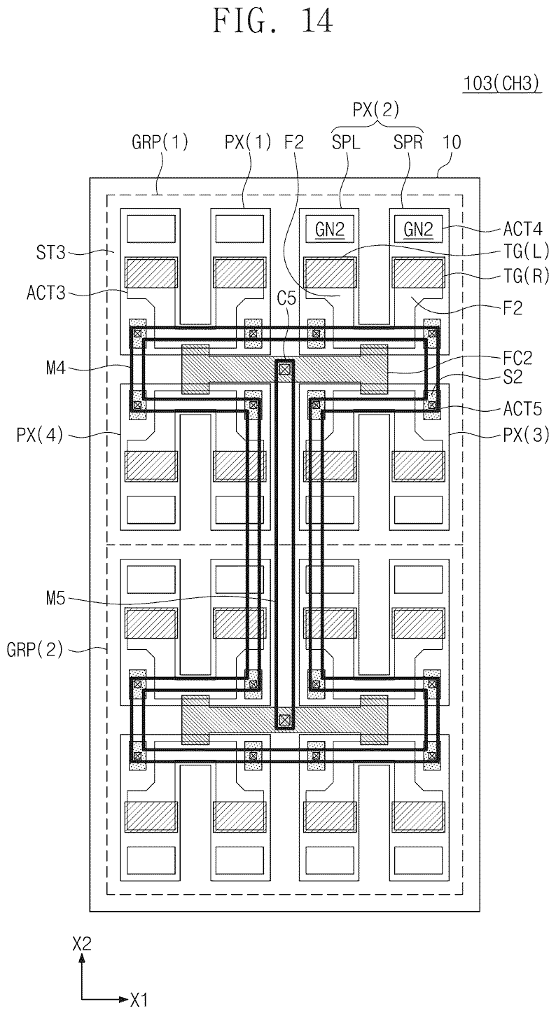

Referring to FIG. 14, the second FD connection line FC2 may extend in the first direction X1 and connect the second floating diffusion regions F2 of the light-receiving regions PX in each of the first and second group regions GRP(1) and GRP(2) in the structure of FIG. 13. That is, one second FD connection line FC2 may traverse the center of the first group region GRP(1) in the first direction X1 and may be in contact with lower surfaces of the second floating diffusion regions F2 belonging to the first group region GRP(1). Another second FD connection line FC2 may traverse the center of the second group region GRP(2) in the first direction X1 and may be in contact with lower surfaces of the second floating diffusion regions F2 belonging to the second group region GRP(2). A cross-section of the second FD connection line FC2 may be the same as/similar to those described with reference to FIGS. 12A and 12B. The second FD connection line FC2 is in contact with the fifth contact plug C5 at the center of the first group region GRP(1). The second FD connection line FC2 is in contact with the fifth contact plug C5 at the center of the second group region GRP(2). The fifth line M5 may connect the fifth contact plug C5 of the center of the first group region GRP(1) to the fifth contact plug C5 of the center of the second group region GRP(2). In a plan view, the fifth line M5 may have a shape of a bar or a line extending in the second direction X2.

The second source regions S2 of the first and second group regions GRP(1) and GRP(2) may be connected to the fourth line M4. A level of the fourth line M4 may be different from a level of the second FD connection line FC2. In a plan view, the fourth line M4 may surround the fifth line M5 as shown in FIG. 14. Accordingly, conversion gain of the second floating diffusion regions F2 may be improved, and noise may be reduced. Other structures may be the same as/similar to those described with reference to FIGS. 1 to 8.

The third semiconductor chip CH3 of FIG. 15 may have a structure in which a portion of the second source regions S2 is not provided in each of the first and second group regions GRP(1) and GRP(2) of FIG. 13. For example, in the first group region GRP(1), the second source regions S2 may be present only in the right side sub region SPR of the first light-receiving region PX(1) and the left side sub region SPL of the second light-receiving region PX(2). In addition, in the second group region GRP(2), the second source regions S2 may be present only in the right side sub region SPR of the fourth light-receiving region PX(4) and the left side sub region SPL of the third light-receiving region PX(3).

Referring to FIGS. 15 and 16, in each of the first and second group regions GRP(1) and GRP(2), the second source regions S2 may be connected to a source connection line MS. The source connection line MS may be formed of the same material as the transfer gate electrode TG. For example, the source connection line MS and the transfer gate electrode TG may both be formed of polysilicon and may be doped with impurities. The quantity of impurities may be the same and/or different. In this case, the source connection line MS and the transfer gate electrode TG may be referred to as having a same base material. Sidewalls of the source connection line MS may be covered with the spacer 12. The source connection line MS may be in contact with lower surfaces of the second source regions S2. A portion of the source connection line MS may be inserted into the third shallow isolation part ST3 and the deep isolation part 10 and in contact with side surfaces of the second source regions S2. The center of the source connection line MS may be in contact with a forty second contact plug C42. The fourth line M4 may connect the forty second contact plug C42 of the first group region GRP(1) to the forty second contact plug C42 of the second group region GRP(2). In a plan view, the fourth line M4 may surround the fifth line M5.

The second semiconductor chip CH2 of the image sensor 103 according at least some embodiments may have one structure among those of FIGS. 1 and 5A to 8. In the image sensor 103 according at least some embodiments, the light-receiving regions PX of two group regions GRP(1) and GRP(2) adjacent to each other may share the driving transistors RX, DCX, SFX, and SLX. Other structures may be the same as/similar to those described with reference to FIGS. 9 and 10.

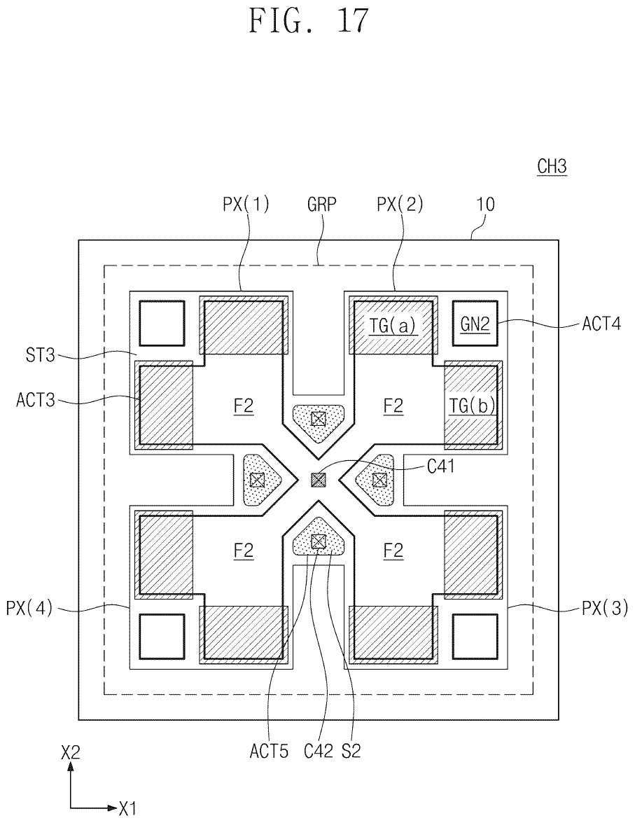

FIG. 17 is a plan view of a third semiconductor chip of an image sensor according to embodiments of the inventive concepts.

Referring to FIGS. 17 and 3, in the third semiconductor chip CH3 according at least some embodiments, the deep isolation part 10 is disposed in the third substrate SB3 and isolates the light-receiving regions PX. The light-receiving regions PX in a 2×2 array adjacent to each other constitute one group region GRP. In each of the light-receiving regions PX, the third shallow isolation part ST3 may be disposed and define the third to fifth active regions ACT3 to ACT5. The third active regions ACT3 of the light-receiving regions PX may be connected to each other at the center of the group region GRP. That is, the deep isolation part 10 and the third shallow isolation part ST3 are not provided at the center of the group region GRP. The second floating diffusion regions F2 of the light-receiving regions PX may be connected to each other at the center of the group region GRP.

The transfer gate electrode TG is disposed on the third active region ACT3 of each of the light-receiving regions PX. The transfer gate electrode TG may include a first sub transfer gate electrode TG(a) and a second sub transfer gate electrode TG(b) spaced apart from each other. Adjacent first sub transfer gate electrode TG(a) and second sub transfer gate electrode TG(b) may be connected by a line, and the same voltage may be applied thereto. The second ground region GN2 may be disposed in the fourth active region ACT4.

The fifth active regions ACT5 may be disposed to surround the center of the group region GRP. The second source regions S2 may be respectively disposed in the fifth active regions ACT5. A forty first contact plug C41 may be disposed on the second floating diffusion region F2 at the center of the group region GRP. The forty second contact plugs C42 may be respectively disposed on the second source regions S2. The second floating diffusion region F2 and the forty first contact plug C41 may be connected to the first floating diffusion region F1 of FIGS. 1 and 5A to 8. The second source regions S2 and the forty second contact plugs C42 may be connected to the first source region S1 of FIGS. 1 and 5A to 8. Accordingly, conversion gain of the second floating diffusion region F2 may be improved, and noise may be reduced. Other structures may be the same as/similar to those described above.

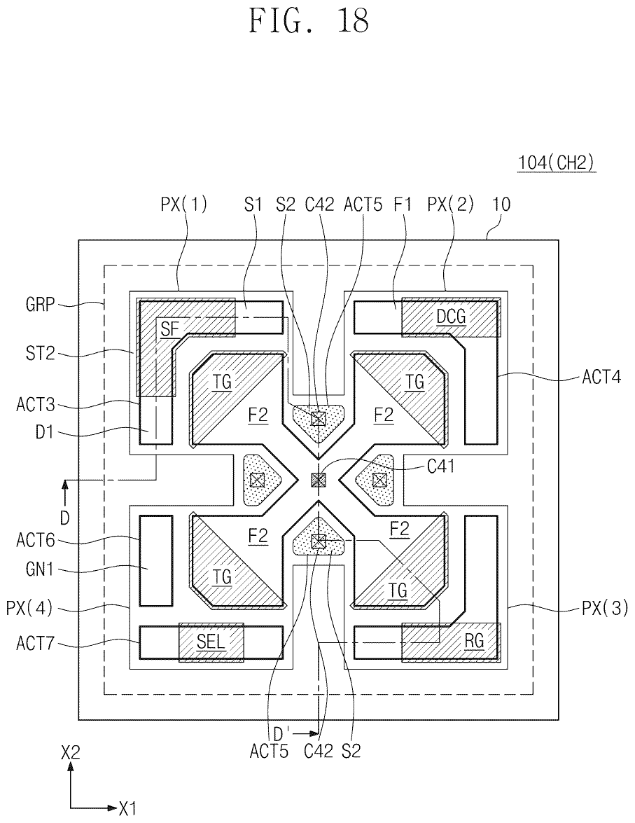

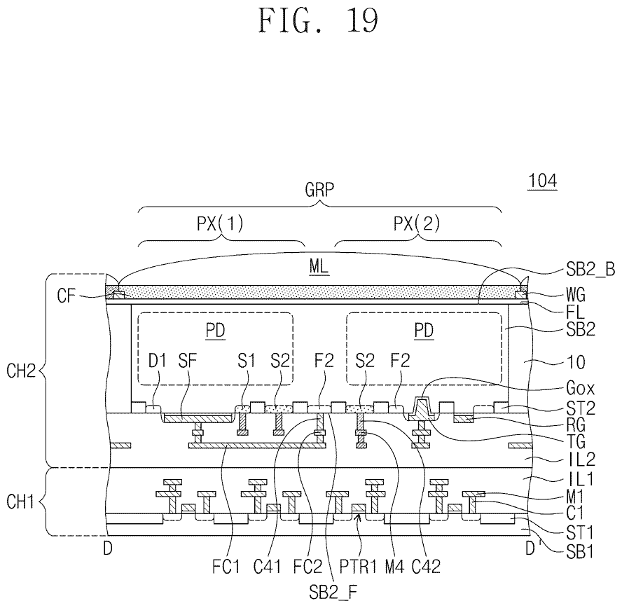

FIG. 18 is a plan view of a second semiconductor chip of an image sensor according to embodiments of the inventive concepts. FIG. 19 is a cross-sectional view taken along line D-D′ of FIG. 18 according to embodiments of the inventive concepts.

Referring to FIGS. 18 and 19, an image sensor 104 according at least some embodiments may include the first semiconductor chip CH1 and the second semiconductor chip CH2 which are sequentially stacked. The first semiconductor chip CH1 may be the same as/similar to the first semiconductor chip CH1 described with reference to FIG. 3. All of the transfer transistors TX and the driving transistors RX, DCX, SFX, and SLX of FIG. 4A may be disposed in the second semiconductor chip CH2. The first semiconductor chip CH1 and the second semiconductor chip CH2 may be electrically connected to each other by a through electrode and/or connection pads.

The second semiconductor chip CH2 according at least some embodiments includes the second substrate SB2 and the second interlayer insulating layer IL2. The deep isolation part 10 is disposed in the second substrate SB2 and isolates the light-receiving regions PX. The light-receiving regions PX(1) to PX(4) in a 2×2 array adjacent to each other and disposed along a clockwise direction constitute one group region GRP. In the light-receiving regions PX, the second shallow isolation part ST2 may be disposed in a front surface SB2_F of the second substrate SB2 and define third to seventh active regions ACT3 to ACT7. The third active regions ACT3 of the light-receiving regions PX may be connected to each other at the center of the group region GRP. That is, the deep isolation part 10 and the second shallow isolation part ST2 are not provided at the center of the group region GRP. The second floating diffusion regions F2 of the light-receiving regions PX may be connected to each other at the center of the group region GRP. The transfer gate electrode TG is disposed on the third active region ACT3 of each of the light-receiving regions PX.

In each of the first to third light-receiving regions PX(1) to PX(3), the fourth active region ACT4 may have an L-shape. The sixth and seventh active regions ACT6 and ACT7 spaced apart from each other may be disposed in the fourth light-receiving region PX(4).

The source follower gate electrode SF may be disposed on the fourth active region ACT4 of the first light-receiving region PX(1). The source follower gate electrode SF may have an L-shape in a plan view. The first source region S1 may be disposed on one side of the source follower gate electrode SF, and the first drain region D1 may be disposed on another side of the source follower gate electrode SF.

The dual conversion gain gate electrode DCG may be disposed on the fourth active region ACT4 of the second light-receiving region PX(2). The first floating diffusion region F1 may be disposed on one side of the dual conversion gain gate electrode DCG.

The reset gate electrode RG may be disposed in the fourth active region ACT4 of the third light-receiving region PX(3). The first ground region GN1 may be disposed in the sixth active region ACT6 of the fourth light-receiving region PX(4), and the selection gate electrode SEL may be disposed in the seventh active region ACT7 of the fourth light-receiving region PX(4).

The fifth active regions ACT5 may be disposed to surround the center of the group region GRP. The second source regions S2 may be respectively disposed in the fifth active regions ACT5. A forty first contact plug C41 may be disposed on the second floating diffusion region F2 at the center of the group region GRP. The forty second contact plugs C42 may be respectively disposed on the second source regions S2. The second floating diffusion region F2 may be connected to the first floating diffusion region F1, e.g., through a second FD connection line FC2. For example, the second FD connection line FC2 may be located below the second floating diffusion regions F2 and the first floating diffusion region F1. Alternatively, a portion of the second FD connection line FC2 may be in contact with side surfaces of the second floating diffusion regions F2 and/or the first floating diffusion region F1. The second source regions S2 may be connected to the first source region S1. Accordingly, conversion gain of the second floating diffusion region F2 may be improved, and noise may be reduced.

The fixed charge layer FL, the color filter CF, and the microlens ML may be sequentially stacked on a rear surface SB2_B of the second substrate SB2. Other structures may be the same as/similar to those described above.

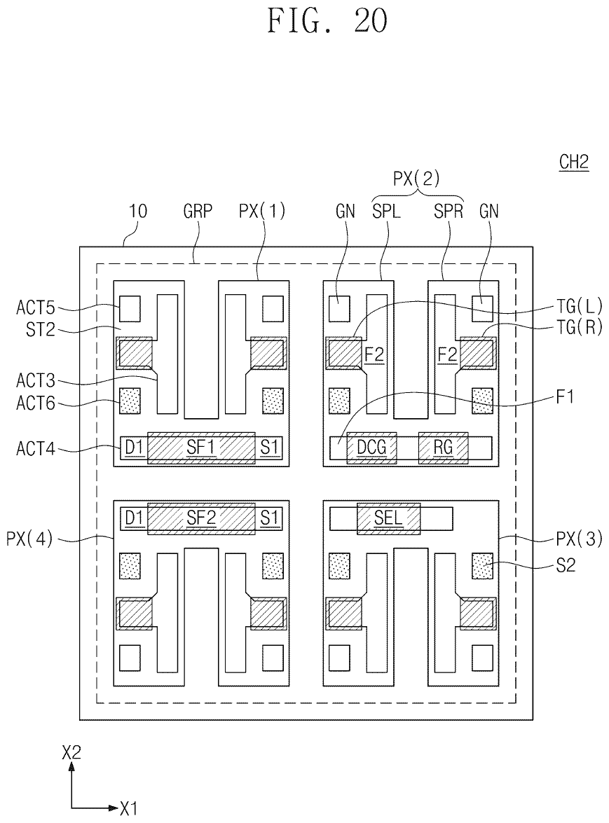

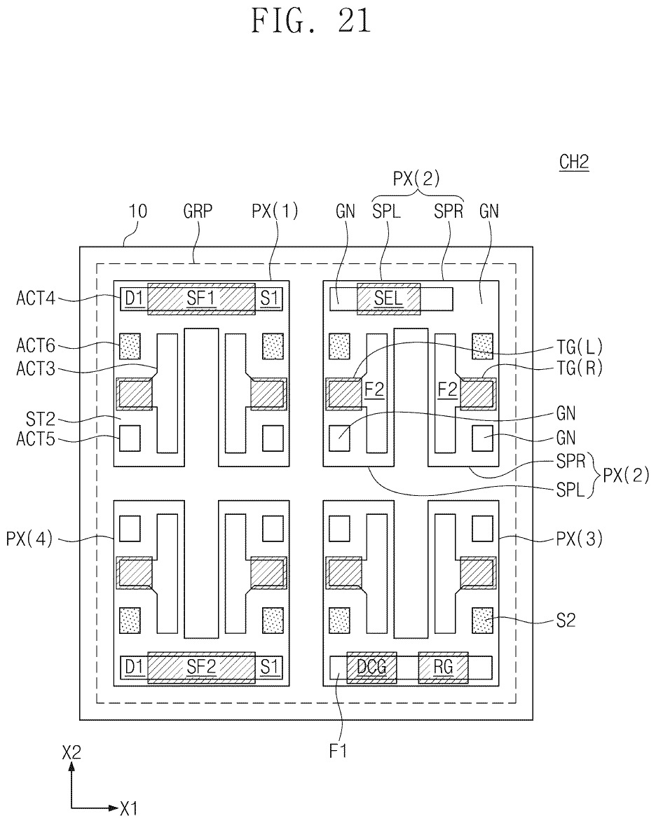

FIGS. 20 and 21 are plan views of a second semiconductor chip of an image sensor according to embodiments of the inventive concepts.

Referring to FIGS. 20 and 21, an image sensor according at least some embodiments may include the first and second semiconductor chips CH1 and CH2 which are stacked as shown in FIG. 19. The second semiconductor chip CH2 includes the second substrate SB2 and the second interlayer insulating layer IL2. The deep isolation part 10 is disposed in the second substrate SB2 and isolates the light-receiving regions PX. The light-receiving regions PX(1) to PX(4) in a 2×2 array adjacent to each other and disposed along a clockwise direction constitute one group region GRP. The light-receiving regions PX(1) to PX(4) may each include the left side sub region SPL and the right side sub region SPR. In each of the light-receiving regions PX, the second shallow isolation part ST2 may be disposed in the front surface SB2_F of the second substrate SB2 and define third to sixth active regions ACT3 to ACT6.

The third active regions ACT3 respectively disposed in the left side sub region SPL and the right side sub region SPR may have a shape in which a letter “T” is rotated by about 90 degrees or about 270 degrees in a plan view. The transfer gate electrode TG is disposed adjacent to the center of each of the third active regions ACT3, and the second floating diffusion region F2 is disposed on one side of the transfer gate electrode TG.

The fourth active regions ACT4 may be respectively disposed in the light-receiving regions PX and have a shape of a bar extending along the first direction X1 in a plan view. In each of the left side sub region SPL and the right side sub region SPR, the fifth active region ACT5 may be adjacent to one side of the third active region ACT3, and the sixth active region ACT6 may be adjacent to another side of the third active region ACT3. A ground region GN may be disposed in the fifth active region ACT5. The second source regions S2 may be disposed in the sixth active regions ACT6.

Referring to FIG. 20, the fourth active regions ACT4 of the first to fourth light-receiving regions PX(1) to PX(4) may be adjacent to the center of the group region GRP.

Referring to FIG. 20, a first source follower gate electrode SF1 may be disposed on the fourth active region ACT4 of the first light-receiving region PX(1). The first source region S1 is disposed on one side of the first source follower gate electrode SF1, and the first drain region D1 is disposed on another side of the first source follower gate electrode SF1.

Referring to FIG. 20, the dual conversion gain gate electrode DCG and the reset gate electrode RG may be disposed on the fourth active region ACT4 of the second light-receiving region PX(2). The first floating diffusion region F1 is disposed on one side of the dual conversion gain gate electrode DCG.

Referring to FIG. 20, the selection gate electrode SEL may be disposed on the fourth active region ACT4 of the third light-receiving region PX(3). A second source follower gate electrode SF2 may be disposed on the fourth active region ACT4 of the fourth light-receiving region PX(4). The first source region S1 is disposed on one side of the second source follower gate electrode SF2, and the first drain region D1 is disposed on another side of the second source follower gate electrode SF2.

Referring to FIG. 20, the first source follower gate electrode SF1 may be connected to the second source follower gate electrode SF2. The first source region S1 of the first light-receiving region PX(1) may be connected to the first source region S1 of the second light-receiving region PX(2). The first drain region D1 of the first light-receiving region PX(1) may be connected to the first drain region D1 of the second light-receiving region PX(2). Accordingly, two source follower transistors SFX may be connected to each other in parallel and constitute a finger type, thereby reducing noise. The second source regions S2 may be disposed around the second floating diffusion regions F2.

Referring to FIG. 21, the fourth active regions ACT4 of the first to fourth light-receiving regions PX(1) to PX(4) may be adjacent to an outer periphery of the group region GRP. The selection gate electrode SEL may be disposed on the fourth active region ACT4 of the second light-receiving region PX(2). The dual conversion gain gate electrode DCG and the reset gate electrode RG may be disposed on the fourth active region ACT4 of the third light-receiving region PX(3). Other structures may be the same as/similar to those described with reference to FIG. 20.

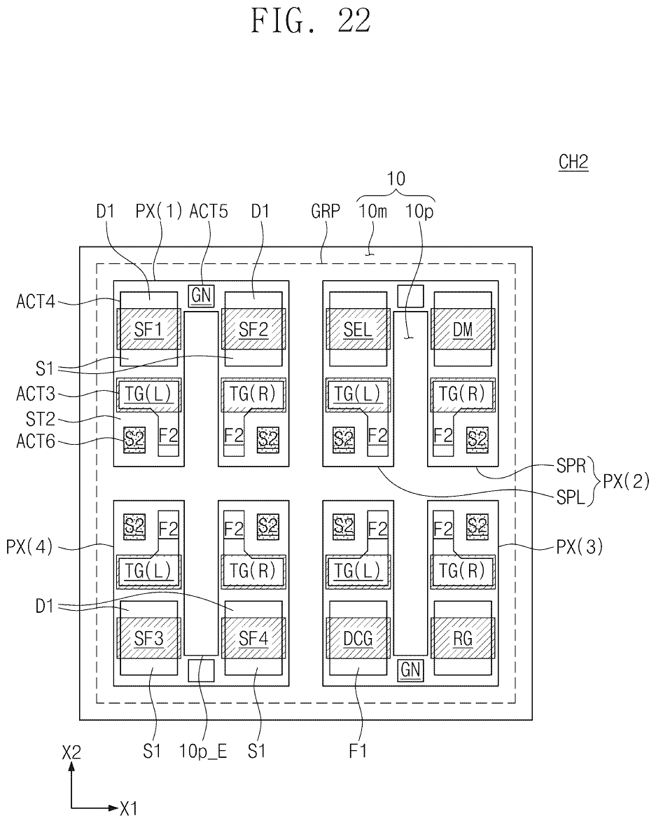

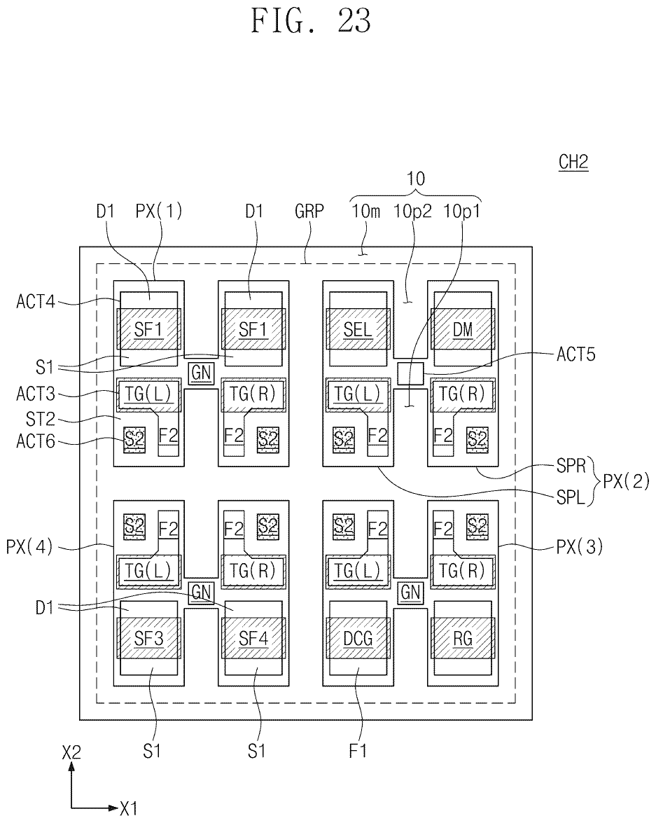

FIGS. 22 and 23 are plan views of a second semiconductor chip of an image sensor according to embodiments of the inventive concepts.

Referring to FIG. 22, an image sensor according at least some embodiments may include the first and second semiconductor chips CH1 and CH2 which are stacked as shown in FIG. 19. The second semiconductor chip CH2 includes the second substrate SB2 and the second interlayer insulating layer IL2. The deep isolation part 10 is disposed in the second substrate SB2 and isolates the light-receiving regions PX. The light-receiving regions PX(1) to PX(4) in a 2×2 array adjacent to each other and disposed along a clockwise direction constitute one group region GRP. The light-receiving regions PX(1) to PX(4) may each include the left side sub region SPL and the right side sub region SPR spaced apart from each other in the first direction X1. In a plan view, a portion of the deep isolation part 10 may be inserted between the left side sub region SPL and the right side sub region SPR and extend in the second direction X2. The deep isolation part 10 may have an isolation main portion 10m isolating the light-receiving regions PX and an isolation protrusion 10p inserted between the left side sub region SPL and the right side sub region SPR. An end portion 10p_E of the isolation protrusion 10p may be spaced apart from the isolation main portion 10m in the second direction X2 at a place adjacent to an edge of a light-receiving region PX. That is, the deep isolation part 10 may be cut at places adjacent to edges of the light-receiving regions PX.

In each of the light-receiving regions PX, the second shallow isolation part ST2 may be disposed on the front surface SB2_F of the second substrate SB2 and define the third to sixth active regions ACT3 to ACT6.

The third active regions ACT3 respectively disposed in the left side sub region SPL and the right side sub region SPR may have a shape in which a letter “L” is respectively rotated by about 90 degrees, about 180 degrees, and/or about 270 degrees in a plan view. The transfer gate electrode TG is disposed adjacent to one side of each of the third active regions ACT3, and the second floating diffusion region F2 is disposed on another side of the third active regions ACT3.

The fourth active regions ACT4 may be respectively disposed in the left side and right side sub regions SPL and SPR and have a shape of a bar extending along the second direction X2 in a plan view. The driving transistors RX, DCX, SFX, and SLX(see FIG. 4A) may be disposed on the fourth active regions ACT4. In one group region GRP, source follower gate electrodes SF1 to SF4 may be respectively disposed in the fourth active regions ACT4 of the first light-receiving region PX(1) and the fourth light-receiving region PX(4) and constitute four source follower transistors SFX with the first drain region D1 and the first source region S1 on two sides of each of the source follower gate electrodes SF1 to SF4. In one group region GRP, the four source follower transistors SFX may be connected to each other in parallel and constitute a finger type, thereby reducing noise.

According at least some embodiments, it is illustrated that one group region GPR includes four source follower transistors SFX, but an embodiment of the inventive concepts is not limited thereto, and one group region GRP may include one to three source follower transistors.

The selection gate electrode SEL may be disposed on the fourth active region ACT4 of the left side sub region SPL of the second light-receiving region PX(2), and a dummy gate electrode DM may be disposed on the fourth active region ACT4 of the right side sub region SPR. The dummy gate electrode DM may not be a gate electrode of a driving transistor that actually operates so as to sense an image and may be formed to prevent a loading effect in a manufacturing process. The dual conversion gain gate electrode DCG may be disposed instead of the dummy gate electrode DM.

The dual conversion gain gate electrode DCG is disposed on the fourth active region ACT4 of the left side sub region SPL of the third light-receiving region PX(3), and the first floating diffusion region F1 is disposed on one side thereof. The second floating diffusion region F2 may be connected to the first floating diffusion region F1. The reset gate electrode RG may be disposed on the fourth active region ACT4 of the right side sub region SPR of the third light-receiving region PX(3).

In each of the light-receiving regions PX, the fifth active region ACT5 is disposed between the end portion 10p_E of the isolation protrusion 10p and the isolation main portion 10m. The ground region GN may be disposed in the fifth active region ACT5.

In each of the left side and right side sub regions SPL and SPR, the sixth active region ACT6 may be disposed to be adjacent to the second floating diffusion region F2 of the third active region ACT3. The second source regions S2 may be disposed in the sixth active regions ACT6. Accordingly, the second source regions S2 may be disposed to be adjacent to and surround the second floating diffusion regions F2. The second source regions S2 may be connected to the first source region S1. Therefore, conversion gain of the second floating diffusion region F2 may be improved, and noise may be reduced. Other structures may be the same as/similar to those described with reference to FIG. 20.

Referring to FIG. 23, in an image sensor according at least some embodiments, the deep isolation part 10 may have the isolation main portion 10m isolating the light-receiving regions PX, and first and second isolation protrusions 10p1 and 10p2 inserted between the left side sub region SPL and the right side sub region SPR. The first and second isolation protrusions 10p1 and 10p2 may be spaced apart from each other at a place adjacent to the center of a light-receiving region PX. That is, the deep isolation part 10 may be cut at places adjacent to the centers of the light-receiving regions PX. In each of the light-receiving regions PX, the fifth active region ACT5 is disposed between the first and second isolation protrusions 10p1 and 10p2. The ground region GN may be disposed in the fifth active region ACT5. Other structures may be the same as/similar to those described with reference to FIG. 22.

In an image sensor according to embodiments of the inventive concepts, a source region of a source follower transistor may be disposed to be adjacent to a floating diffusion region or to surround a floating diffusion region. The source region of the source follower transistor may be interposed between a ground region and the floating diffusion region. Accordingly, parasitic capacitances between the floating diffusion region and peripheral conductive structures may be reduced, conversion gain of the floating diffusion region may be improved, and noise may be reduced. Therefore, the image sensor capable of realizing a clear image may be provided.

Although embodiments of the present invention have been described with reference to the accompanying drawings, those of ordinary skill in the art could easily understood that the present invention can be carried out in other specific forms without changing the technical concept or essential features. Therefore, the above embodiments should be considered illustrative and should not be construed as limiting. The embodiments of FIGS. 1 to 23 may be combined with each other.

What is claimed is:

1. An image sensor comprising:
a first substrate;
a first floating diffusion region in the first substrate;
a source follower gate electrode on the first substrate; and
a first source region on one side of the source follower gate electrode, in the first substrate, and spaced apart from the first floating diffusion region,
wherein, in a plan view, the first source region includes
a main portion adjacent to a sidewall of the source follower gate electrode, and
a protrusion protruding from the main portion and adjacent to the first floating diffusion region.

2. The image sensor of claim 1, wherein the protrusion at least partially surrounds the first floating diffusion region in the plan view.

3. The image sensor of claim 1, further comprising:
a ground region adjacent to the first floating diffusion region such that, in the plan view, the protrusion is between the ground region and the first floating diffusion region.

4. The image sensor of claim 3, further comprising:
a first contact plug on the first floating diffusion region;
a second contact plug on the protrusion of the first source region; and
a third contact plug on the ground region,
wherein, in the plan view, the second contact plug is between the first contact plug and the third contact plug.

5. The image sensor of claim 1, wherein in the plan view, the first floating diffusion region has a first side surface parallel to a first direction and a second side surface parallel to a second direction intersecting the first direction, and
the protrusion comprises a first protrusion adjacent to the first side surface and a second protrusion adjacent to the second side surface.

6. The image sensor of claim 1, further comprising:
a first line connecting the first floating diffusion region to the source follower gate electrode; and
a second line connected to the first source region,
wherein the second line is located at the same level as the first line, and
wherein the second line at least partially surrounds the first line in the plan view.

7. The image sensor of claim 1, further comprising:
a second substrate on an upper surface of the first substrate;
second source regions in the second substrate, the second source regions spaced apart from each other; and
a second floating diffusion region between at least two of the second source regions in the second substrate,
wherein the second floating diffusion region is electrically connected to the first floating diffusion region, and
the second source regions are electrically connected to the first source region.

8. The image sensor of claim 7, wherein the second source regions are spaced apart from each other such that the second source regions surround at least a portion of the second floating diffusion region.

9. The image sensor of claim 7, further comprising:
a first interlayer insulating layer covering the upper surface of the first substrate;
a second interlayer insulating layer covering a lower surface of the second substrate;
first contact plugs in the first interlayer insulating layer and connected to the first source region;
second contact plugs in the second interlayer insulating layer and connected to the second source regions;
first connection pads at an upper end of the first interlayer insulating layer and connected to the first contact plugs; and
second connection pads at a lower end of the second interlayer insulating layer and connected to the second contact plugs,
wherein the second connection pads are electrically connected to respective first connection pads of the first connection pads.

10. The image sensor of claim 9, further comprising:
a third contact plug in the first interlayer insulating layer and connected to the first floating diffusion region;
a fourth contact plug in the second interlayer insulating layer and connected to the second floating diffusion region;
a third connection pad at the upper end of the first interlayer insulating layer and connected to the third contact plug; and
a fourth connection pad at the lower end of the second interlayer insulating layer and connected to the fourth contact plug,
wherein the fourth connection pad is electrically connected to the third connection pad,
the third connection pad is between the first connection pads, and
the fourth connection pad is between the second connection pads.

11. The image sensor of claim 1, further comprising:
a second floating diffusion region spaced apart from the first floating diffusion region;
a shallow isolation part between the first floating diffusion region and the second floating diffusion region;
a connection line on the shallow isolation part, the connection line electrically connecting the first floating diffusion region and the second floating diffusion region; and
a first transfer gate electrode adjacent to the first floating diffusion region,
wherein the connection line includes a same base material as the first transfer gate electrode.

12. The image sensor of claim 11, wherein a portion of the first transfer gate electrode is inserted into the first substrate, and
a portion of the connection line is in the shallow isolation part and in contact with side surfaces of both the first floating diffusion region and the second floating diffusion region.

13. An image sensor comprising:
a first substrate;
a first floating diffusion region in the first substrate;
a source follower gate electrode on the first substrate;
a ground region in the first substrate; and
a first source region in the first substrate, the first source region on one side of the source follower gate electrode, spaced apart from the first floating diffusion region, and interposed between the first floating diffusion region and the ground region.

14. The image sensor of claim 13, wherein in a plan view, the first source region at least partially surrounds the first floating diffusion region.

15. The image sensor of claim 13, further comprising:
a first contact plug on the first floating diffusion region;
a second contact plug on the first source region; and
a third contact plug on the ground region,
wherein, with respect to a first horizontal direction, the second contact plug is between the first contact plug and the third contact plug.

16. The image sensor of claim 13, further comprising:
a first line connecting the first floating diffusion region to the source follower gate electrode; and
a second line connected to the first source region,
wherein the second line is located at the same level as the first line, and
in a plan view, the second line at least partially surrounds the first line.

17. An image sensor comprising:
a first substrate;
a source follower gate electrode on the first substrate;
a first source region on one side of the source follower gate electrode and in the first substrate;
a first floating diffusion region in the first substrate and spaced apart from the first source region;
a first interlayer insulating layer covering an upper surface of the first substrate;
a second substrate on the first interlayer insulating layer such that the first interlayer insulating layer is between the first substrate and the second substrate;
a second interlayer insulating layer between the first interlayer insulating layer and the second substrate;
a second floating diffusion region in the second substrate;
a transfer gate electrode on a lower surface of the second substrate and adjacent to at least a portion of the second floating diffusion region;
second source regions in the second substrate and at least partially surrounding the second floating diffusion region;
a color filter on the second substrate; and
a microlens on the color filter,
wherein the second source regions are electrically connected to the first source region, and
the second floating diffusion region is electrically connected to the first floating diffusion region.

18. The image sensor of claim 17, wherein in a plan view, the first source region at least partially surrounds the first floating diffusion region.

19. The image sensor of claim 17, further comprising:
a first line in the first interlayer insulating layer and connecting the source follower gate electrode to the first floating diffusion region; and
a second line in the first interlayer insulating layer and connected to the first source region,
wherein in a plan view, the second line at least partially surrounds the first line.

20. The image sensor of claim 17, further comprising:
a ground region in the first substrate and adjacent to the first floating diffusion region such that, in a plan view, the first source region is interposed between the first floating diffusion region and the ground region.
